(19) United States
(12) Patent Application Publication
(10) Pub. No.: US 2026/0347525 A1
(43) Pub. Date: Nov. 5, 2026

(54) RESIN COMPOSITION, ADHESIVE MEMBER, AND ELECTRONIC APPARATUS INCLUDING THE ADHESIVE MEMBER

(71) Applicant: Samsung Display Co., Ltd., Yongin-si (KR)

(72) Inventor: Yosuke SAITO, Yokohama-shi (JP)

(21) Appl. No.: 19/661,590

(22) Filed: Apr. 28, 2026

(30) Foreign Application Priority Data
May 1, 2025 (JP) 2025-076162

(51) Int. Cl. C08F 222/10; C08F 2/46; C09J 133/10; H05K 5/03

(52) U.S. Cl. CPC C08F 222/1065; C08F 2/46; C09J 133/10; H05K 5/03

(57) ABSTRACT

Provided is a resin composition including at least one (meth)acrylate oligomer including a (meth)acrylate monomer that has a dicyclopentenyl skeleton in a side chain, at least one (meth)acrylate monomer including a (meth)acryloyl group, at least one urethane (meth)acrylate oligomer, and at least one photoradical polymerization initiator, wherein the resin composition does not include a volatile organic solvent. The resin composition according to one or more embodiments may have a 180° peel strength of about 2000 gf/25 mm or greater for at least one of a glass substrate or a polymer substrate at room temperature after photocuring, and have a yellow index of about 1 or less after a light resistance test according to DIN75220. Accordingly, the resin composition according to one or more embodiments may exhibit excellent or suitable adhesive strength and excellent or suitable light resistance after curing.

### CROSS-REFERENCE TO RELATED APPLICATION

The present application claims priority to and the benefit of Japanese Patent Application No. 2025-076162, filed on May 1, 2025, in the Japan Patent Office, the entire disclosure of which is incorporated herein by reference.

### BACKGROUND

### 1. Field

Embodiments of the present disclosure are related to a resin composition, an adhesive member formed from the resin composition, and an electronic apparatus including the adhesive member.

### 2. Description of the Related Art

Various suitable types (kinds) of display devices used for multimedia devices such as television sets, mobile phones, tablet computers, navigation systems, and game consoles have been developed. The display devices include multiple components forming the display devices, and adhesive members are between the components. Resin compositions are provided to form the adhesive members, and the adhesive members included in the display devices are required or desired to stably bond the components of the display devices prevent or minimize degradation in display quality.

### SUMMARY

The present disclosure provides a resin composition exhibiting high adhesive properties and excellent or suitable light resistance after curing, an adhesive member formed from the resin composition, and an electronic apparatus including the adhesive member.

One or more embodiments of the present disclosure include a resin composition including at least one (meth)acrylate oligomer including a (meth)acrylate monomer that has a dicyclopentenyl skeleton in a side chain, at least one (meth)acrylate monomer including a (meth)acryloyl group, at least one urethane (meth)acrylate oligomer, and at least one photoradical polymerization initiator, wherein the resin composition does not include a volatile organic solvent.

In one or more embodiments, the (meth)acrylate oligomer may have a glass transition temperature of about 80 °C or greater.

In one or more embodiments, the (meth)acrylate oligomer may have a weight-average molecular weight of about 5,000 g/mol to about 20,000 g/mol.

In one or more embodiments, the (meth)acrylate oligomer may have a polydispersity index of about 1.0 to about 3.0.

In one or more embodiments, the (meth)acrylate monomer that has the dicyclopentenyl skeleton in a side chain may be dicyclopentenyl (meth)acrylate or dicyclopentenyl oxyethyl(meth)acrylate.

In one or more embodiments, the resin composition may have a 180° peel strength of about 2000 gf/25 mm or greater for at least one of a glass substrate or a polymer substrate at room temperature after photocuring.

In one or more embodiments, the resin composition may be provided through inkjet printing or dispensing.

In one or more embodiments of the present disclosure, an adhesive member includes a polymer derived from a resin composition, wherein the resin composition includes at least one (meth)acrylate oligomer including a (meth)acrylate monomer that has a dicyclopentenyl skeleton in a side chain, at least one (meth)acrylate monomer including a (meth)acryloyl group, at least one urethane (meth)acrylate oligomer, and at least one photoradical polymerization initiator, and does not include a volatile organic solvent.

In one or more embodiments, the adhesive member may have a 180° peel strength of about 2000 gf/25 mm or greater for at least one of a glass substrate or a polymer substrate at room temperature.

In one or more embodiments, the adhesive member may have a yellow index of about 1 or less after a light resistance test according to DIN75220.

In one or more embodiments, the (meth)acrylate oligomer may have a glass transition temperature of about 80 °C or greater.

In one or more embodiments, the (meth)acrylate oligomer may have a weight-average molecular weight of about 5,000 g/mol to about 20,000 g/mol.

In one or more embodiments, the (meth)acrylate oligomer may have a polydispersity index of about 1.0 to about 3.0.

In one or more embodiments, the (meth)acrylate monomer that has the dicyclopentenyl skeleton in a side chain may be dicyclopentenyl (meth)acrylate or dicyclopentenyl oxyethyl(meth)acrylate.

In one or more embodiments, the resin composition may be provided through inkjet printing or dispensing.

In one or more embodiments of the present disclosure, an electronic apparatus includes a display module, a window on the display module, and an adhesive member between the display module and the window and including a polymer derived from a resin composition, wherein the resin composition includes at least one (meth)acrylate oligomer including a (meth)acrylate monomer that has a dicyclopentenyl skeleton in a side chain, at least one (meth)acrylate monomer including a (meth)acryloyl group, at least one urethane (meth)acrylate oligomer, and at least one photoradical polymerization initiator, and does not include a volatile organic solvent.

In one or more embodiments, the adhesive member may have a 180° peel strength of about 2000 gf/25 mm or greater for at least one of a glass substrate or a polymer substrate at room temperature.

In one or more embodiments, the adhesive member may have a yellow index of about 1 or less after a light resistance test according to DIN75220.

In one or more embodiments, the window may include a base layer and a printing layer between the adhesive member and the base layer, and the resin composition provided on one surface of the display module or one surface of the window may be cured by light passing through the printing layer for irradiation to form the adhesive member.

In one or more embodiments, the electronic apparatus may further include at least one of a processor, a memory, or a power module.

### BRIEF DESCRIPTION OF THE DRAWINGS

The accompanying drawings are included to provide a further understanding of the present disclosure, and are incorporated in and constitute a part of this disclosure. The drawings illustrate embodiments of the present disclosure and, together with the description, serve to explain principles of the present disclosure. In the drawings:

FIG. 1 is a perspective view that shows an electronic apparatus according to one or more embodiments;

FIG. 2 is an exploded perspective view that shows a display device according to one or more embodiments;

FIG. 3 is a cross-sectional view that shows a portion corresponding to line I-I′ of FIG. 1;

FIG. 4 is a cross-sectional view that shows a portion of a display device according to one or more embodiments;

FIG. 5A is a view that shows a method for preparing an adhesive member according to one or more embodiments;

FIG. 5B is a view that shows a method for preparing an adhesive member according to one or more embodiments;

FIG. 5C is a view that shows a method for preparing an adhesive member according to one or more embodiments;

FIG. 5D is a view that shows a method for preparing an adhesive member according to one or more embodiments;

FIG. 6A is a view that shows a method for preparing an adhesive member according to one or more embodiments;

FIG. 6B is a view that shows a method for preparing an adhesive member according to one or more embodiments;

FIG. 6C is a view that shows a method for preparing an adhesive member according to one or more embodiments;

FIG. 7 is a cross-sectional view that shows a display device according to one or more embodiments;

FIG. 8 is a cross-sectional view that shows a display device according to one or more embodiments;

FIG. 9 is a view that shows a vehicle in which a display device according to one or more embodiments is arranged;

FIG. 10 is a block diagram of an electronic apparatus according to one or more embodiments;

FIG. 11 shows schematic views of electronic apparatuses according to various suitable embodiments;

FIG. 12A is a perspective view that shows an electronic apparatus according to one or more embodiments;

FIG. 12B is a perspective view that shows an electronic apparatus according to one or more embodiments;

FIG. 12C is a plan view that shows an electronic apparatus according to one or more embodiments;

FIG. 12D is a perspective view that shows an electronic apparatus according to one or more embodiments;

FIG. 13 is an exploded perspective view that shows a display device according to one or more embodiments; and

FIG. 14 is a cross-sectional view that shows a portion corresponding to line II-II′ of FIG. 13.

### DETAILED DESCRIPTION

In this disclosure, it will be understood that when an element (or a region, a layer, a portion, and/or the like) is referred to as being “on”, “connected to” or “coupled to” another element, it may be directly on, connected to, or coupled to the other element, or other elements may be therebetween.

Like reference numerals or symbols refer to like elements throughout. In the drawings, the thickness, ratio, and size of the elements are exaggerated for effectively describing the technical contents. The term “and/or” includes any and all combinations of one or more of the associated listed elements.

It will be understood that, although the terms “first”, “second”, and/or the like may be used herein to describe various suitable elements, the elements are not to be limited by these terms. These terms are only used to distinguish one element, component, region, layer or section from another element, component, region, layer or section. For instance, a first element, component, region, layer or section discussed below could be termed a second element, component, region, layer or section without departing from the scope of the present disclosure. Similarly, a second element, component, region, layer or section could be termed a first element, component, region, layer or section. The singular expressions “a”, “an”, and “the” are intended to include the plural forms as well, unless the context clearly indicates otherwise.

For example, the terms “below”, “under”, “on the lower side”, “above”, “over”, “on the upper side”, and/or the like may be used to describe the relationships between the elements illustrated in the drawings. These terms are relative concepts and are described on the basis of the directions indicated in the drawings.

It will be further understood that the terms “comprises, includes, has” and/or “comprising, including, that has”, when used in this disclosure, specify the presence of stated features, numbers, steps, operations, elements, components or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as that have a meaning that is consistent with their meaning in the context of the relevant art and will not be interpreted in an idealized or overly formal sense unless expressly so defined herein.

Hereinafter, a resin composition according to one or more embodiments of the present disclosure, an adhesive member according to one or more embodiments, and a display device including the same will be described herein. A display device according to one or more embodiments may be applied to various suitable electronic apparatuses. An electronic apparatus according to one or more embodiments may include a display device, and may further include a module or a device that has additional functions in addition to the display device.

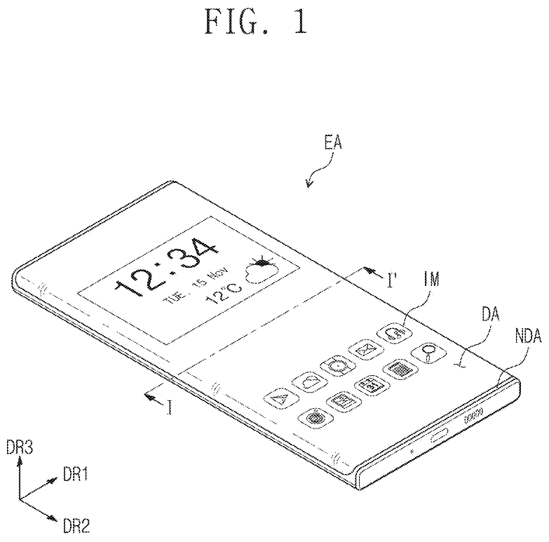

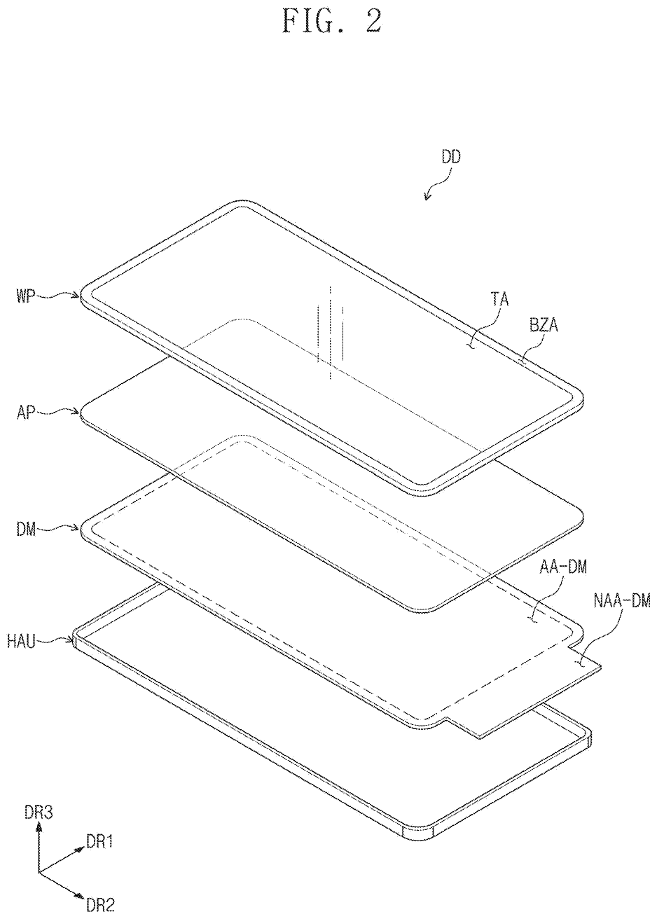

FIG. 1 is a perspective view that shows an electronic apparatus according to one or more embodiments. FIG. 2 is an exploded perspective view of a display device according to one or more embodiments.

An electronic apparatus EA according to one or more embodiments shown in FIG. 1 may be a device activated according to electrical signals. For example, the electronic apparatus EA may be personal computers, laptop computers, personal digital terminals, game consoles, portable electronic apparatuses, television sets, monitors, outdoor billboards, car navigation systems, or wearable devices, but an embodiment is not limited thereto. In FIG. 1, a mobile phone is shown as the electronic apparatus EA by way of example.

The electronic apparatus EA according to one or more embodiments may display an image IM through a display region DA. The display region DA may include a plane defined by the first directional axis DR1 and the second directional axis DR2. The display region DA may further include a curved surface bent from one side of the plane defined by the first directional axis DR1 and the second directional axis DR2. The electronic apparatus EA according to one or more embodiments shown in FIG. 1 is shown to include two curved surfaces each bent from both sides of the plane defined by the first directional axis DR1 and the second directional axis DR2. However, the shape of the display region DA is not limited thereto. For example, the display region DA may include only the plane defined by the first directional axis DR1 and the second directional axis DR2, and the display region DA may further include curved surfaces each bent from at least two sides of the plane defined by the first directional axis DR1 and the second directional axis DR2 (e.g., four curved surfaces each bent from four sides of the plane).

The electronic apparatus EA according to one or more embodiments may be flexible. The term “flexible” indicates a property of being bendable, and may include all from a structure being completely foldable to a structure being bendable up to several nanometers. For example, the electronic apparatus EA may be a foldable electronic apparatus. For example, the electronic apparatus EA may be rigid.

The non-display region NDA may be a region adjacent to the display region DA. The non-display region NDA may surround the display region DA. Accordingly, the shape of the display region DA may be defined substantially by the non-display region NDA. However, this is presented as an example, and the non-display region NDA may be adjacent to only one side of the display region DA, or may not be provided. The display region DA may be provided in various suitable shapes and is not limited to any one embodiment.

FIG. 1 and the following drawings show first to third directional axes DR1 to DR3, and directions indicated by the first to third directional axes DR1, DR2, and DR3 described herein are relative concepts, and may thus be changed to other directions. For example, the directions indicated by the first to third directional axes DR1, DR2, and DR3 may be described herein as first to third directions, and the same reference numerals may be used. The first directional axis DR1 and the second directional axis DR2 herein may be perpendicular to each other, and the third directional axis DR3 may be a normal direction with respect to a plane defined by the first directional axis DR1 and the second directional axis DR2.

A thickness direction of the electronic apparatus EA may be parallel to the third directional axis DR3 which is a normal direction with respect to a plane defined by the first directional axis DR1 and the second directional axis DR2. As described herein, a front surface (or an upper surface, upper portion surface, upper side) and a rear surface (or a lower surface, lower portion surface, lower side) of members constituting the electronic apparatus EA may be defined with respect to the third directional axis DR3. For example, as described herein, a direction in which the third directional axis DR3 extends is parallel to the thickness direction, and the front surface (or an upper surface, upper portion surface, upper side) indicates a surface (or direction) adjacent to a surface on which the image IM is displayed, and the rear surface (or a lower surface, lower portion surface, lower side) indicates a surface (or direction) spaced apart from a surface on which the image IM is displayed. Herein, the term ‘plane’ refers to a plane parallel to the plane defined by the first directional axis DR1 and the second directional axis DR2, and the term ‘cross-section’ refers to a plane perpendicular to the plane defined by the first directional axis DR1 and the second directional axis DR2 and parallel to the thickness direction DR3.

Referring to FIG. 2, the display device DD may include a display module DM, a window WP on the display module DM, and an adhesive member AP between the display module DM and the window WP. For example, the display device DD may further include a housing HAU accommodating the display module DM.

In the display device DD shown in FIG. 2, the window WP and the housing HAU may be bonded together to form an outer portion of the display device DD. The housing HAU may be below the display module DM. The housing HAU may include a material that has a relatively greater rigidity. For example, the housing HAU may include a plurality of frames and/or plates formed of glass, plastic, or metal. The housing HAU may provide a place for accommodation. The display module DM may be accommodated in the accommodation space so as to be protected from an external impact.

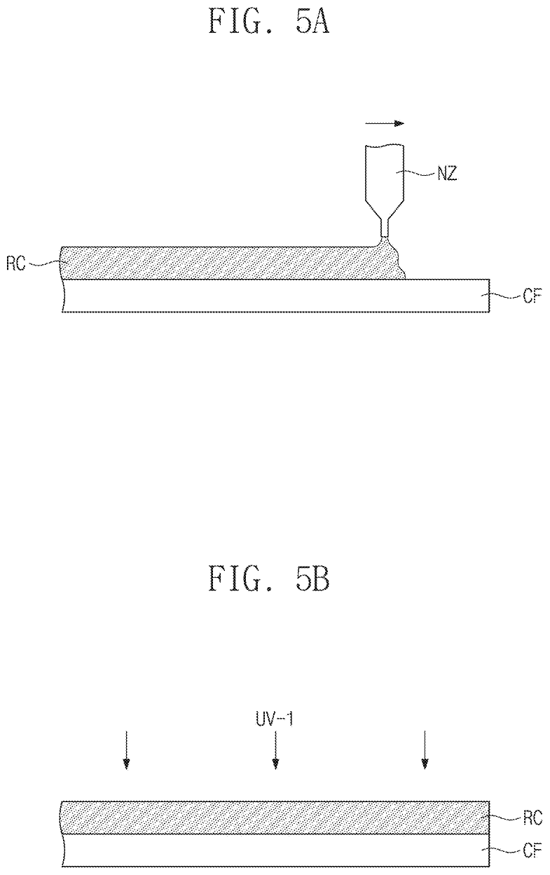

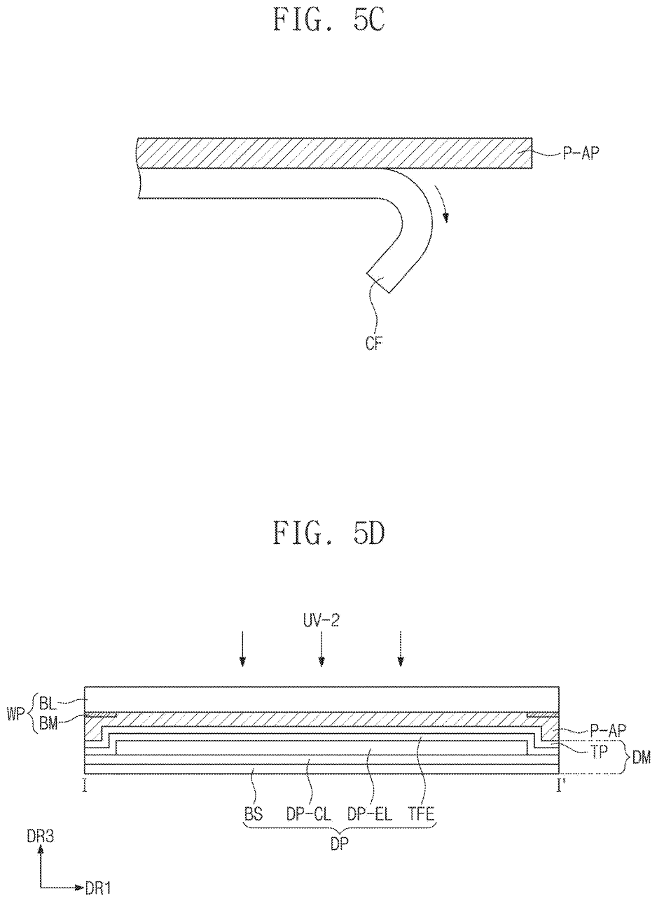

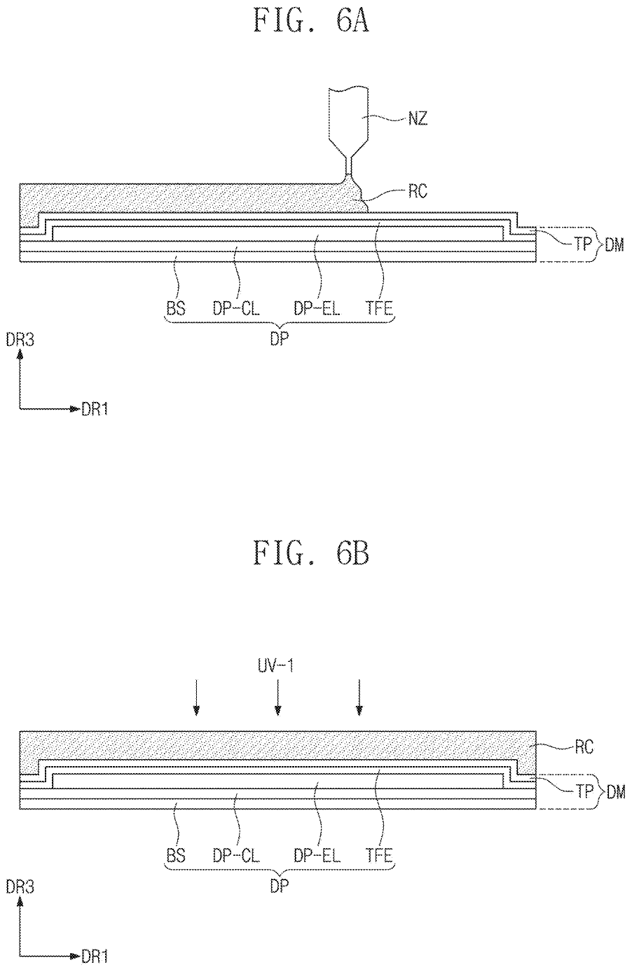

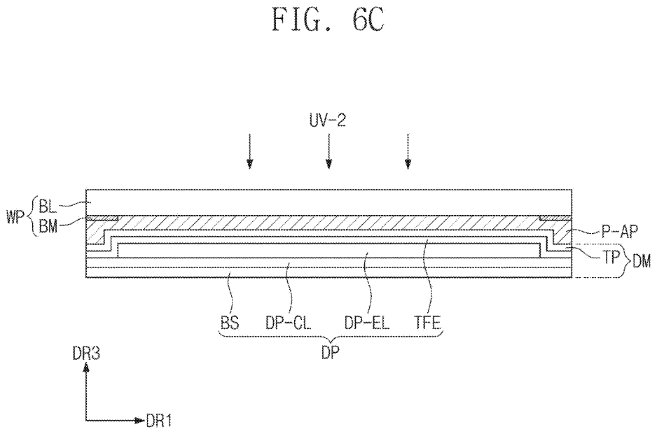

In one or more embodiments, the adhesive member AP may include a polymer derived from a resin composition RC (FIGS. 5A and 6A). The adhesive member AP may be formed by photocuring the resin composition RC (FIGS. 5A and 6A). The display module DM and the window WP may be bonded through the adhesive member AP. The adhesive member AP according to one or more embodiments is formed from the resin composition RC (FIGS. 5A and 6A) according to one or more embodiments, and may thus exhibit excellent or suitable adhesive reliability. For example, the adhesive member AP according to one or more embodiments may be prevented from discoloration caused by external light (e.g., UV light).

The window WP may include a transmission region TA and a bezel region BZA. The transmission region TA may overlap at least a portion of the active region AA-DM of the display module DM. The transmission region TA may be an optically transparent region. The image IM (FIG. 1) may be provided to users through the transmission region TA.

The bezel region BZA may be a region that has a relatively lower light transmittance than the transmission region TA. The bezel region BZA may define a shape of the transmission region TA. The bezel region BZA may be adjacent to the transmission region TA and may surround the transmission region TA.

The bezel region BZA may have a color. The bezel region BZA covers the peripheral region NAA-DM of the display module DM, and may thus prevent the peripheral region NAA-DM from being viewed from the outside. However, an embodiment is not limited to what is shown, and the bezel region BZA may be adjacent to only one side of the transmission region TA, and at least a portion thereof may not be provided.

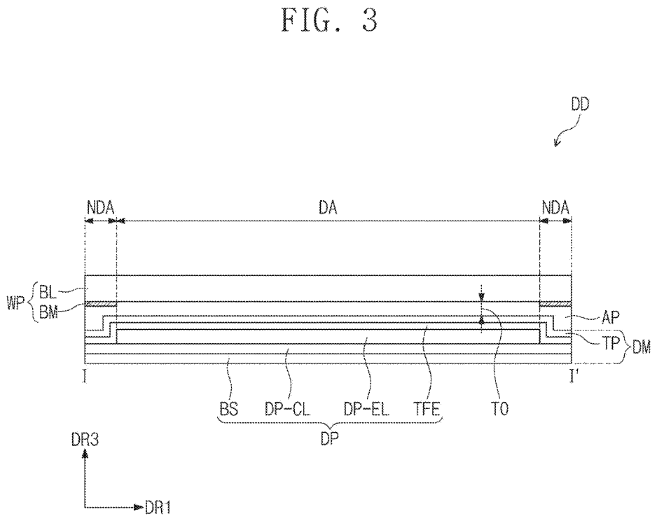

FIG. 3 is a cross-sectional view that shows a portion corresponding to line I-I′ of FIG. 1. FIG. 3 is a cross-sectional view that shows the display module DM, the adhesive member AP, and the window WP of FIG. 2. For example, FIG. 3 is a cross-sectional view that shows a display device DD according to one or more embodiments.

Referring to FIG. 3, the display module DM may include a display panel DP and an input sensing portion TP on the display panel DP. The display panel DP may be configured to substantially generate images. The display panel DP may include a base substrate BS, a circuit layer DP-CL on the base substrate BS, a display element layer DP-EL on the circuit layer DP-CL, and an encapsulation layer TFE covering the display element layer DP-EL. The adhesive member AP may be between the display panel DP and the window WP. The adhesive member AP may be between the window WP and the input sensing portion TP on the display panel DP.

The components of the display panel DP shown in FIG. 3 are an example and the components of the display panel DP are not limited thereto. For example, the display panel DP may include a liquid crystal display element, and for example, the encapsulation layer TFE may not be provided.

The base substrate BS may provide a base surface on which the circuit layer DP-CL is arranged. The base substrate BS may be a flexible substrate that is bendable, foldable, rollable, and/or the like. The base substrate BS may be a glass substrate, a metal substrate, or a polymer substrate. However, an embodiment is not limited thereto, and the base substrate BS may be an inorganic layer, an organic layer, or a composite material layer including an inorganic layer and an organic layer.

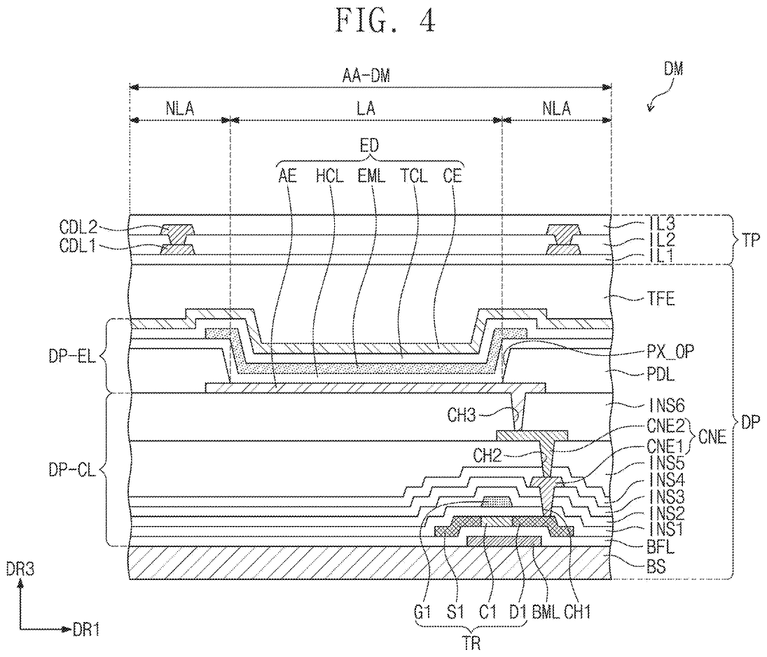

The circuit layer DP-CL may include an insulating layer, a semiconductor pattern, a conductive pattern, a signal line, and/or the like. For example, the circuit layer DP-CL may include a switching transistor and a driving transistor for driving a light emitting element ED (FIG. 4) of the display element layer DP-EL.

The display element layer DP-EL may include the light emitting element (FIG. 4) emitting light. For example, the light emitting element (FIG. 4) may include organic light emitting materials, inorganic light emitting materials, organic-inorganic light emitting materials, quantum dots, quantum rods, micro LEDs, or nano LEDs.

The encapsulation layer TFE may be on the display element layer DP-EL. The encapsulation layer TFE may serve to protect the light emitting element layer DP-EL from moisture, oxygen, and/or foreign substances such as dust particles. The encapsulation layer TFE may include at least one inorganic layer. For example, the encapsulation layer TFE may include an inorganic layer, an organic layer, and an inorganic layer, which are sequentially stacked.

The input sensing portion TP may be on the display panel DP. For example, the input sensing portion TP may be directly on the encapsulation layer TFE of the display panel DP. In embodiments, an adhesive layer may be between the input sensing portion TP and the display panel DP.

Herein, when a component is directly arranged/provided on another component, it indicates that a third component is not arranged/provided between one component and another component. For example, when a component is ‘directly arranged/provided’ on another component, it indicates that a component is in ‘contact’ with another component.

The input sensing portion TP may sense external inputs to convert the inputs into input signals, and provide the input signals to the display panel DP. For example, in the display device DD according to one or more embodiments, the input sensing portion TP may be a touch sensing portion sensing a touch. The input sensing portion TP may recognize a user's direct touch, a user's indirect touch, a direct touch of an object, or an indirect touch of an object.

The input sensing portion TP may sense at least any one of a location of a touch or strength (pressure) of a touch applied from the outside. In one or more embodiments, the input sensing portion TP may have various suitable structures or be formed of various suitable materials, and is not limited to any one embodiment. For example, the input sensing portion TP may sense external inputs using a capacitive method. The display panel DP may receive input signals from the input sensing portion TP and generate images corresponding to the input signals.

The window WP may include a base layer BL and a printing layer BM. Although not shown, the window WP may further include at least one functional layer provided on the base layer BL. For example, the functional layer may be a hard coating layer, an anti-fingerprint coating layer, and/or the like, but an embodiment is not limited thereto.

The base layer BL may be a glass substrate. In embodiments, the base layer BL may be a plastic substrate. For example, the base layer BL may be formed of polyimide, polyacrylate, polymethylmethacrylate, polycarbonate, polyethylenenaphthalate, polyvinylidene chloride, polyvinylidene difluoride, polystyrene, ethylene vinylalcohol copolymer, or a combination thereof.

The printing layer BM may be on one surface of the base layer BL. The printing layer BM may be provided on a lower surface of the base layer BL adjacent to the display module DM. The printing layer BM may be on an edge region of the base layer BL. The printing layer BM may be an ink printing layer. For example, the printing layer BM may be a layer formed by including pigment or dye. The printing layer BM may be formed including a light absorbing material, or may be formed including a black pigment or a black dye. However, this is presented as an example, and an embodiment is not limited thereto. In the window WP, the bezel region BZA (FIG. 2) may be a portion in which the printing layer BM is provided.

The adhesive member AP may have a thickness range TO of about 50 μm to about 200 μm. For example, the adhesive member AP may have a thickness range TO of about 50 μm to about 100 μm. However, this is presented as an example, and the thickness TO of the adhesive member AP is not limited thereto.

In one or more embodiments, the adhesive member AP may have a 180° peel strength of about 2000 gf/25 mm or greater for at least one of a glass substrate or a polymer substrate at room temperature. “The room temperature” may mean a temperature of 15 °C to 30 °C, but an embodiment is not limited thereto. An adhesive that has a 180° peel strength of less than about 2000 gf/25 mm for a glass substrate and a polymer substrate has low adhesive strength and peels off from the adjacent components of a display device (e.g., a display module and/or a window). Conversely, the adhesive member AP according to one or more embodiments that has a 180° peel strength of about 2000 gf/25 mm or greater for at least one of a glass substrate or a polymer substrate at room temperature may exhibit excellent or suitable adhesive strength. For example, the display device DD including the adhesive member AP according to one or more embodiments may exhibit excellent or suitable reliability.

In one or more embodiments, the adhesive member AP may have a yellow index (YI) of about 1 or less after a light resistance test according to DIN75220. The usage environment of a display device includes exposure to external light such as UV light. The light resistance test is performed to determine the resistance of adhesive members to discoloration and fading upon exposure to UV light and/or the like.

An adhesive member that has a yellow index of greater than about 1 after a light resistance test according to DIN75220 has low resistance to discoloration and fading upon exposure to UV light and/or the like, and exhibits discoloration and/or fading as exposure time to external light such as UV light accumulates. The adhesive member exhibiting discoloration and/or fading degrades the display quality of images generated from a display module below the adhesive member. The images generated from the display module passes through the adhesive member and is provided to users. Conversely, in one or more embodiments, the adhesive member AP that has a yellow index of about 1 or less after a light resistance test according to DIN75220 has high resistance to discoloration, fading, and/or the like upon exposure to UV light and/or the like, and may thus exhibit excellent or suitable light resistance. For example, the display device DD including the adhesive member AP according to one or more embodiments may exhibit excellent or suitable display quality.

FIG. 4 is a cross-sectional view specifically that shows the display module DM of FIG. 3. Components of the display module DM shown in FIG. 4 are presented as an example, and an embodiment is limited thereto.

In FIG. 4, the base substrate BS may include a single layer or multiple layers. For example, the base substrate BS may include a first synthetic resin layer, a multi- or single-layered inorganic layer, and a second synthetic resin layer on the multi- or single-layered inorganic layer. Each of the first synthetic resin layer and the second synthetic resin layer may include a polyimide-based resin. For example, each of the first synthetic resin layer and the second synthetic resin layer may include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin. Herein, a “~~based” resin may be considered as including a functional group of “~~”.

The display panel DP may include a transistor TR and a light emitting element ED. The transistor TR and the light emitting element ED may be on the base substrate BS. Although one transistor TR is shown in FIG. 4, the display panel DP may include a plurality of transistors and at least one capacitor for driving the light emitting element ED.

The circuit layer DP-CL may be on the base substrate BS. The circuit layer DP-CL may include a shielding electrode BML, a transistor TR, a connection electrode CNE, and a plurality of insulating layers BFL and INS1 to INS6. The plurality of insulating layers BFL and INS1 to INS6 may include a buffer layer BFL and first to sixth insulating layers INS1 to INS6. However, the stack structure of the circuit layer DP-CL shown in FIG. 4 is presented as an example, and the stack structure of the circuit layer DP-CL may change depending on components of the display panel DP and processes of the circuit layer DP-CL.

The shielding electrode BML may be on the base substrate BS. The shielding electrode BML may overlap the transistor TR. The shielding electrode BML may protect the transistor TR by blocking light incident on the transistor TR from a lower portion of the display panel DP. The shielding electrode BML may include a conductive material. When a voltage is applied to the shielding electrode BML, threshold voltage of the transistor TR on the shielding electrode BML may be maintained. However, an embodiment is not limited thereto, and the shielding electrode BML may be a floating electrode. The shielding electrode BML may not be provided.

The buffer layer BFL may be on the base substrate BS to cover the shielding electrode BML. The buffer layer BFL may include an inorganic layer. The buffer layer BFL may improve the bonding force between the base substrate BS and a semiconductor pattern or a conductive pattern on the buffer layer BFL.

The transistor TR may include a source S1, a channel C1, a drain D1, and a gate G1. The source S1, the channel C1, and the drain D of the transistor TR may be formed from the semiconductor pattern. The semiconductor pattern of the transistor TR may include polysilicon, amorphous silicon, or metal oxide, and may be applied without limitation as long as it has semiconductor properties.

The semiconductor pattern may include a plurality of regions divided according to the level of conductivity. In the semiconductor pattern, a region doped with a dopant or reduced with metal oxide may have high conductivity and may substantially serve as a source electrode and a drain electrode of the transistor TR. The region that has high conductivity in the semiconductor pattern may correspond to the source S1 and the drain D1 of the transistor TR. In the semiconductor pattern, a region undoped, doped at a low concentration, or non-reduced with metal oxide, thereby that has low conductivity, may correspond to the channel C1 (or active) of the transistor TR.

The first insulating layer INS1 may cover the semiconductor pattern of the transistor TR and be on the buffer layer BFL. The gate G1 of the transistor TR may be on the first insulating layer INS1. When viewed on a plane, the gate G1 may overlap the channel C1 of the transistor TR. The gate G1 may serve as a mask in the process of doping the semiconductor pattern of the transistor TR.

The second insulating layer INS2 may cover the gate G1 and be on the first insulating layer INS1. The third insulating layer INS3 may be on the second insulating layer INS2.

The connection electrode CNE may include a first connection electrode CNE1 and a second connection electrode CNE2 to electrically connect the transistor TR and the light emitting element ED. However, the components of the connection electrode CNE that electrically connect the transistor TR and the light emitting element ED is not limited thereto, and one of the first and second connection electrodes CNE1 and CNE2 may not be provided or an additional connection electrode may be further included.

The first connection electrode CNE1 may be on the third insulating layer INS3. The first connection electrode CNE1 may be connected to the drain D1 through a first contact hole CH1 passing through the first to third insulating layers INS1 to INS3. The fourth insulating layer INS4 may cover the first connection electrode CNE1 and be on the third insulating layer INS3. The fifth insulating layer INS5 may be on the fourth insulating layer INS4.

The second connection electrode CNE2 may be on the fifth insulating layer INS5. The second connection electrode CNE2 may be connected to the first connection electrode CNE1 through a second contact hole CH2 passing through the fourth and fifth insulating layers INS4 and INS5. The sixth insulating layer INS6 may cover the second connection electrode CNE2 and be on the fifth insulating layer INS5.

The first to sixth insulating layers INS1 to INS6 may each include an inorganic layer or an organic layer. For example, the inorganic layer may include at least one selected from among aluminum oxide, titanium oxide, silicon oxide, silicon oxynitride, zirconium oxide, or hafnium oxide. The organic layer may include at least any one selected from among an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin.

The display element layer DP-EL may include a pixel defining film PDL and a light emitting element ED. The light emitting element ED may include a first electrode AE, a hole control layer HCL, an emission layer EML, an electron control layer TCL, and a second electrode CE.

The first electrode AE may be on the sixth insulating layer INS6. The first electrode AE may be connected to the second connection electrode CNE2 through a third contact hole CH3 passing through the sixth insulating layer INS6. The first electrode AE may be electrically connected to the drain D1 of the transistor TR through the first and second connection electrodes CNE1 and CNE2.

The first electrode AE may be formed of a metal material, a metal alloy, or a conductive compound. The first electrode AE may be an anode or a cathode. For example, the first electrode AE may be a pixel electrode. The first electrode AE may be a transmissive electrode, a transflective electrode, or a reflective electrode. The first electrode AE may include at least one selected from among Ag, Mg, Cu, Al, Pt, Pd, Au, Ni, Nd, Ir, Cr, Li, Ca, LiF, Mo, Ti, W, In, Sn, and Zn, two or more compounds selected therefrom, two or more mixtures selected therefrom, or an oxide thereof.

When the first electrode AE is a transmissive electrode, the first electrode AE may include a transparent metal oxide, such as indium tin oxide (ITO), indium zinc oxide (IZO), zinc oxide (ZnO), and indium tin zinc oxide (ITZO). When the first electrode AE is a transflective electrode or a reflective electrode, the first electrode AE may include Ag, Mg, Cu, Al, Pt, Pd, Au, Ni, Nd, Ir, Cr, Li, Ca, LiF/Ca (a stack structure of LiF and Ca), LiF/AI (a stack structure of LiF and Al), Mo, Ti, W, a compound thereof, or a mixture thereof (e.g., a mixture of Ag and Mg). In embodiments, the first electrode AE may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), and/or the like. For example, the first electrode AE may have a three-layer structure of ITO/Ag/ITO, but is not limited thereto. For example, an embodiment is not limited thereto, and the first electrode AE may include the above-described metal materials, a combination of two or more metal materials selected from the above-described metal materials, or oxides of the above-described metal materials.

The pixel defining film PDL may be on the sixth insulating layer INS6. The pixel defining film PDL may be formed of a polymer resin. For example, the pixel defining film PDL may be formed including a polyacrylate-based resin or a polyimide-based resin. For example, the pixel defining film PDL may be formed by further including an inorganic material in addition to the polymer resin. The pixel defining film PDL may be formed including a light absorbing material, or may be formed including a black pigment or a black dye. The pixel defining film PDL including a black pigment or black dye may form a black pixel defining film. When forming the pixel defining film PDL, carbon black may be used as a black pigment or a black dye, but an embodiment is not limited thereto.

For example, the pixel defining film PDL may be formed of an inorganic material. For example, the pixel defining film PDL may be formed of an inorganic material such as silicon nitride (SiNₓ), silicon oxide (SiOₓ), or silicon nitride (SiOₓN_{y}).

A light emitting opening PX_OP exposing a portion of the first electrode AE may be defined in the pixel defining film PDL. A portion of the first electrode AE exposed by the light emitting opening PX_OP may be defined as a light emitting region LA.

The active region AA-DM of the display module DM may include the light emitting region LA and a light blocking region NLA. A region in which the pixel defining film PDL is arranged may correspond to the light blocking region NLA. The light blocking region NLA may surround the light emitting region LA in the active region AA-DM.

The hole control layer HCL may be on the first electrode AE and the pixel defining film PDL. The hole control layer HCL may be provided as a common layer overlapping the light emitting region LA and the light blocking region NLA. The hole control layer HCL may include at least one of a hole transport layer, a hole injection layer, or an electron blocking layer. The hole control layer HCL may include known hole injection materials and/or known hole transport materials.

The emission layer EML may be on the hole control layer HCL. The emission layer EML may be in a region corresponding to the light emitting opening PX_OP. In embodiments, the emission layer EML may be provided as a common layer. The emission layer EML may include an organic light emitting material and/or an inorganic light emitting material. For example, the emission layer EML may emit color light of any one of red, green, and blue. For example, the emission layer EML may emit blue light.

The electron control layer TCL may be on the emission layer EML. The electron control layer TCL may be provided as a common layer that overlaps the light emitting region LA and the light blocking region NLA. The electron control layer TCL may include at least one of an electron transport layer, an electron injection layer, or a hole blocking layer. The electron control layer TCL may include known electron injection materials and/or known electron transport materials.

The second electrode CE may be on the electron control layer TCL. The second electrode CE may be provided as a common layer that overlaps the light emitting region LA and the light blocking region NLA.

The second electrode CE may be a common electrode. The second electrode CE may be a cathode or an anode. For example, when the first electrode AE is an anode, the second electrode CE may be a cathode, and when the first electrode AE is a cathode, the second electrode CE may be an anode.

The second electrode CE may be a transmissive electrode, a transflective electrode, or a reflective electrode. When the second electrode CE is a transmissive electrode, the second electrode CE may be formed of a transparent metal oxide, for example, indium tin oxide (ITO), indium zinc oxide (IZO), zinc oxide (ZnO), indium tin zinc oxide (ITZO), and/or the like.

When the second electrode CE is a transflective electrode or a reflective electrode, the second electrode CE may include Ag, Mg, Cu, Al, Pt, Pd, Au, Ni, Nd, Ir, Cr, Li, Ca, LiF/Ca, LiF/AI, Mo, Ti, Yb, W, a compound thereof, or a mixture thereof (e.g., AgMg, AgYb, and/or MgYb). In embodiments, the second electrode CE may have a multi-layer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), and/or the like. For example, the second electrode CE may include the above-described metal materials, a combination of two or more metal materials selected from the above-described metal materials, or oxides of the above-described metal materials.

The encapsulation layer TFE may be on the second electrode CE and may thus cover the light emitting element ED. The encapsulation layer TFE may include a plurality of thin films. For example, the encapsulation layer TFE may include inorganic layers on the second electrode CE and an organic layer between the inorganic layers. The inorganic film may protect the light emitting element ED from moisture/oxygen, and the organic film may protect the light emitting element ED from foreign substances, such as dust particles.

The input sensing portion TP may include a first sensing insulating layer IL1, a second sensing insulating layer IL2, and a third sensing insulating layer IL3. The input sensing portion TP may include at least one conductive layer on the sensing insulating layers. The input sensing portion TP may include a first conductive layer CDL1 and a second conductive layer CDL2.

The first sensing insulating layer IL1 may be on the encapsulation layer TFE. The first sensing insulating layer IL1 may include at least one inorganic insulating layer. The first sensing insulating layer IL1 may be in contact with the encapsulation layer TFE. In embodiments, the first sensing insulating layer IL1 may not be provided, and for example, the first conductive layer CDL1 may contact the encapsulation layer TFE.

The first conductive layer CDL1 may be on the first sensing insulating layer IL1. The first conductive layer CDL1 may include a plurality of first conductive patterns. The plurality of first conductive patterns may be on the first sensing insulating layer IL1. The second sensing insulating layer IL2 may be on the first sensing insulating layer IL1 to cover at least a portion of the first conductive layer CDL1.

The second conductive layer CDL2 may be on the second sensing insulating layer IL2. The second conductive layer CDL2 may include a plurality of second conductive patterns. The plurality of second conductive patterns may be on the second sensing insulating layer IL2. The plurality of second conductive patterns may each be connected to the plurality of first conductive patterns through a contact hole formed in the second sensing insulating layer IL2.

The plurality of first conductive patterns of the first conductive layer CDL1 and the plurality of second conductive patterns of the second conductive layer CDL2 may each be to correspond to the light blocking region NLA. The plurality of first conductive patterns of the first conductive layer CDL1 and the plurality of second conductive patterns of the second conductive layer CDL2 may each correspond to a mesh pattern.

The third sensing insulating layer IL3 may be on the second sensing insulating layer IL2 and may cover the second conductive layer CDL2. The second sensing insulating layer IL2 and the third sensing insulating layer IL3 may each include an inorganic insulating layer or an organic insulating layer.

The first conductive layer CDL1 and the second conductive layer CDL2 each may have a single-layered structure or may have a multi-layered structure stacked along the third direction DR3. The single-layered conductive layers CDL1 and CDL2 may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), and indium zinc tin oxide (IZTO). For example, the transparent conductive layer may include a conductive polymer such as PEDOT, metal nanowire, graphene, and/or the like.

The multi-layered conductive layers CDL1 and CDL2 may include metal layers. For example, the metal layers may have a three-layer structure of titanium (Ti)/aluminum (AI)/titanium (Ti). The multi-layered conductive layers CDL1 and CDL2 may include at least one metal layer and at least one transparent conductive layer.

FIGS. 5A-5D are views schematically that show a method for manufacturing an adhesive member AP from a resin composition RC according to one or more embodiments. For example, the method for preparing an adhesive member AP may include providing a resin composition RC on a substrate CF, providing first light UV-1 to the resin composition RC to form a preliminary adhesive member P-AP, and providing second light UV-2 to the preliminary adhesive member P-AP to form an adhesive member AP. In the description of FIG. 5A-5D, content that overlaps the one described with reference to FIGS. 1-4 will not be described again, and differences will be mainly described.

Referring to FIG. 5A, the resin composition RC according to one or more embodiments may be provided on the substrate CF. The resin composition RC may be provided onto the substrate CF through a nozzle NZ. For example, the substrate CF on which the resin composition RC is provided may include polyethylene terephthalate (PET). The substrate CF is a temporary substrate used to form the adhesive member AP (FIG. 3) from the resin composition RC, and may be used without limitation as long as it is easily detached after the resin composition RC is cured. One surface of the substrate CF on which the resin composition RC is provided may be subjected to release treatment.

The resin composition RC according to one or more embodiments may be provided through inkjet printing or dispensing. In one or more embodiments, a liquid resin composition RC may be provided in a uniform amount and/or at a uniform rate. FIG. 5A shows that the resin composition RC is provided through the nozzle NZ, but the device for providing the resin composition RC is not limited to thereto.

The resin composition RC according to one or more embodiments may include at least one (meth)acrylate oligomer including a (meth)acrylate monomer that has a dicyclopentenyl skeleton in a side chain, at least one (meth)acrylate monomer including a (meth)acryloyl group, at least one urethane (meth)acrylate oligomer, and at least one photoradical polymerization initiator. In one or more embodiments, the resin composition may not include a volatile organic solvent. Herein, the (meth)acryloyl group indicates an acryloyl group or a methacryloyl group, and the (meth)acryl indicates acryl or methacryl.

The resin composition RC according to one or more embodiments may include at least one (meth)acrylate oligomer including a (meth)acrylate monomer that has a dicyclopentenyl skeleton in a side chain. The resin composition RC includes a (meth)acrylate oligomer including dicyclopentenyl that has an unsaturated bond, and thus the adhesive member AP (FIG. 3) formed by curing the resin composition RC may have a 180° peel strength of about 2000 gf/25 mm or greater for at least one of a glass substrate or a polymer substrate at room temperature, as described above. For example, the adhesive member AP may have a yellow index (YI) of about 1 or less after a light resistance test according to DIN75220. Accordingly, the resin composition RC according to one or more embodiments may exhibit excellent or suitable adhesive reliability and excellent or suitable light resistance after curing. The (meth)acrylate monomer that has the dicyclopentenyl skeleton in a side chain may be dicyclopentenyl (meth)acrylate or dicyclopentenyl oxyethyl(meth)acrylate.

In one or more embodiments, the (meth)acrylate oligomer may have a glass transition temperature of about 80 °C or greater. For example, the (meth)acrylate oligomer may have a glass transition temperature of about 100 °C or greater. The adhesive member AP (FIG. 3) formed from the resin composition RC including a (meth)acrylate oligomer that has a glass transition temperature of about 80 °C or greater may satisfy 180° peel strength and yellow index (YI) characteristics described above.

In one or more embodiments, the (meth)acrylate oligomer may have a weight-average molecular weight of about 5,000 g/mol to about 20,000 g/mol. The weight-average molecular weight of the (meth)acrylate oligomer may be a value derived by standard polystyrene conversion using gel permeation chromatography. For example, the (meth)acrylate oligomer may have a weight-average molecular weight of about 9,000 g/mol to about 15,000 g/mol. The adhesive member AP (FIG. 3) formed from the resin composition RC including a (meth)acrylate oligomer that has a weight-average molecular weight of about 5,000 g/mol to about 20,000 g/mol may satisfy 180° peel strength and yellow index (YI) characteristics described above.

In one or more embodiments, the (meth)acrylate oligomer may have a polydispersity index (PDI) of about 1.0 to about 3.0. The polydispersity index is a value obtained by dividing weight-average molecular weight (Mw) by number-average molecular weight (Mn). A larger polydispersity index value indicates a wider molecular weight distribution from low molecular weight to high molecular weight, and a smaller polydispersity index value indicates a narrower molecular weight distribution from low molecular weight to high molecular weight. The adhesive member AP (FIG. 3) formed from the resin composition RC including a (meth)acrylate oligomer that has a polydispersity index of about 1.0 to about 3.0 may satisfy 180° peel strength and yellow index (YI) characteristics described above.

The resin composition according to one or more embodiments may include at least one (meth)acrylate monomer containing a (meth)acryloyl group. The (meth)acrylate monomer containing a (meth)acryloyl group may include at least one of 4-hydroxybutyl acrylate (4-HBA), isodecyl acrylate (IDAA), tetrahydrofurfuryl acrylate (THF-A), or isobornyl acrylate (IBXA). However, this is presented as an example, and the resin composition RC may further include a (meth)acrylate monomer containing a (meth)acryloyl group other than the listed monomers.

The resin composition RC according to one or more embodiments may include at least one urethane (meth)acrylate oligomer. In the resin composition RC, the urethane (meth)acrylate oligomer may include UV-3300B (urethane acrylate oligomer, Mitsubishi Chemical Corporation). However, this is presented as an example, and the urethane (meth)acrylate oligomer included in the resin composition RC is not limited thereto.

The resin composition RC according to one or more embodiments may include at least one photoradical polymerization initiator. When the resin composition RC includes a plurality of photoradical polymerization initiators, different photoradical polymerization initiators may be activated by ultraviolet rays that have different central wavelengths.

For example, the photoradical polymerization initiator may include at least one of 2,2-dimethoxy-1,2-diphenylethan-1-one, 1-hydroxy cyclohexyl-phenylketone, 2-hydroxy-2-methyl-1-phenyl-1-propanone, 2-hydroxy-1-[4-(2-hydroxyethoxy)phenyl]-2-methyl-1-propanone, or 2-hydroxy-1-{4-[4-(2-hydroxy-2-methyl-propionyl)-benzyl]-phenyl}-2-methylpropan-1-one.

For example, the photoradical polymerization initiator may include at least one of 2-methyl-1 [4-(methylthio)phenyl]-2-morpholinopropan-1-one, 2-benzyl-2-dimethylamino-1-(4-morpholinophenyl)-butanone-1, 2-dimethylamino-2-(4-methyl-benzyl)-1-(4-morpholin-4-yl-phenyl)-butan-1-one, 2,4,6-trimethylbenzoyl-diphenylphosphine oxide, ethyl(2,4,6-trimethylbenzoyl)phenyl phosphinate, phenylbis(2,4,6-trimethylbenzoyl)phosphine oxide, [1-(4-phenylsulfanylbenzoyl)heptylideneamino]benzoate, [1-[9-ethyl-6-(2-methylbenzoyl)carbazol-3-yl]ethylideneamino]acetate, or bis(2,4-cyclopentadienyl)bis[2,6-difluoro-3-(1-pyrryl)phenyl]titanium(IV).

The resin composition according to one or more embodiments may not include a volatile organic solvent. The solvent refers to a liquid used to dissolve materials (e.g., monomers, oligomers, and/or the like) constituting a composition. The resin composition including a volatile organic solvent requires a drying time after application of the resin composition. In contrast, the resin composition RC according to one or more embodiments that does not include volatile organic solvent may not require a drying time after application of the resin composition, and may be provided through inkjet printing or dispensing, thereby exhibiting excellent or suitable manufacturing efficiency.

Referring to FIG. 5B, the first light UV-1 may be provided to the resin composition RC applied at a constant thickness on the substrate CF. The liquid resin composition RC may be cured by the first light UV-1 to form a preliminary adhesive member P-AP (FIG. 5C). The first light UV-1 may be UV light. FIG. 5B shows that the first light UV-1 is directly irradiated to the resin composition RC applied on the substrate CF to form the preliminary adhesive member P-AP, but an embodiment is not limited thereto. A carrier film may be on the resin composition RC applied to a uniform thickness, and the carrier film may transmit UV light.

Referring to FIGS. 5C and 5D, the preliminary adhesive member P-AP formed by irradiating the resin composition RC with the first light UV-1 (FIG. 5B) may be detached from the substrate CF and provided on one side of the window WP or on one side of the display module DM. One surface of the preliminary adhesive member P-AP may be laminated on one surface of the window WP or one surface of the display module DM, and one surface of the display module DM or one surface of the window WP that is not attached may be attached to the other surface of the preliminary adhesive member P-AP. Thereafter, the preliminary adhesive member P-AP may be irradiated with second light UV-2 to form the adhesive member AP (FIG. 3). The second light UV-2 may be UV light. The second light UV-2 may be provided from an upper portion of the window WP, and the window WP may transmit the second light UV-2. The second light UV-2 may be transmitted through the window WP and provided to the preliminary adhesive member P-AP. For example, the second light UV-2 may be transmitted through the printing layer BM and provided to the preliminary adhesive member P-AP.

A region of the preliminary adhesive member P-AP overlapping the printing layer BM may be irradiated with a smaller amount of second light UV-2 than another region of the preliminary adhesive member P-AP non-overlapping the printing layer BM. The resin composition RC according to one or more embodiments includes a (meth)acrylate oligomer including a (meth)acrylate monomer that has a dicyclopentenyl skeleton in a side chain, and may thus exhibit excellent or suitable adhesive strength after curing even when irradiated with a relatively small amount of the second light UV-2 for curing.

Accordingly, the resin composition RC according to one or more embodiments may have a 180° peel strength of about 2000 gf/25 mm or greater for at least one of a glass substrate or a polymer substrate at room temperature after curing by the light UV-1 and UV-2. Accordingly, the resin composition RC according to one or more embodiments may exhibit excellent or suitable adhesive strength after curing. For example, the adhesive member AP (FIG. 3) formed from the resin composition RC according to one or more embodiments may exhibit excellent or suitable adhesive strength even under the printing layer BM.

The resin composition RC according to one or more embodiments may have a yellow index (YI) of about 1 or less after a light resistance test according to DIN75220 after curing by light UV-1 and UV-2. Accordingly, the resin composition RC according to one or more embodiments may exhibit excellent or suitable light resistance after curing. For example, the adhesive member AP (FIG. 3) formed from the resin composition RC according to one or more embodiments may exhibit excellent or suitable light resistance even under the printing layer BM.

FIGS. 5A-5D show that the adhesive member AP (FIG. 3) is formed by curing the resin composition RC twice (i.e., curing by providing light twice), but an embodiment is not limited thereto. For example, the adhesive member AP (FIG. 3) may be formed by curing the resin composition RC once, or the adhesive member AP (FIG. 3) may be formed by curing the resin composition RC three or more times.

FIGS. 6A-6C are views schematically that show another method for manufacturing an adhesive member AP from a resin composition RC according to one or more embodiments. In the description of FIGS. 6A-6C, content that overlaps the one described with reference to FIGS. 1-5D will not be described again, and differences will be mainly described.

The method for manufacturing an adhesive member AP shown in FIGS. 6A-6C may include providing a resin composition RC on a display module DM, providing first light UV-1 to the resin composition RC to form a preliminary adhesive member P-AP, and providing second light UV-2 to the preliminary adhesive member P-AP to form an adhesive member AP. The manufacturing method shown in FIGS. 6A-6C differs from the manufacturing method shown in FIGS. 5A-5D in that the resin composition RC is provided on the display module DM.

The resin composition RC may be directly provided on one side of the display module DM or one side of the window WP. FIG. 6A shows that the resin composition RC is directly provided on one surface of the display module DM.

Referring to FIG. 6B, the first light UV-1 may be provided to the uniformly applied resin composition RC. As the first light UV-1 is provided to the resin composition RC, the preliminary adhesive member P-AP may be formed. The window WP may be provided on the preliminary adhesive member P-AP. Referring to FIG. 6C, the second light UV-2 may pass through the window WP and be provided to the preliminary adhesive member P-AP. For example, the second light UV-2 may be transmitted through the printing layer BM and provided to the preliminary adhesive member P-AP. The preliminary adhesive member P-AP may be cured through the second light UV-2 to form the adhesive member AP (FIG. 3).

The adhesive member AP (FIG. 3) formed from the resin composition RC according to one or more embodiments may exhibit high adhesive strength and excellent or suitable light resistance. For example, the adhesive member AP (FIG. 3) formed from the resin composition RC according to one or more embodiments may exhibit high adhesive strength and excellent or suitable light resistance even under the printing layer BM.

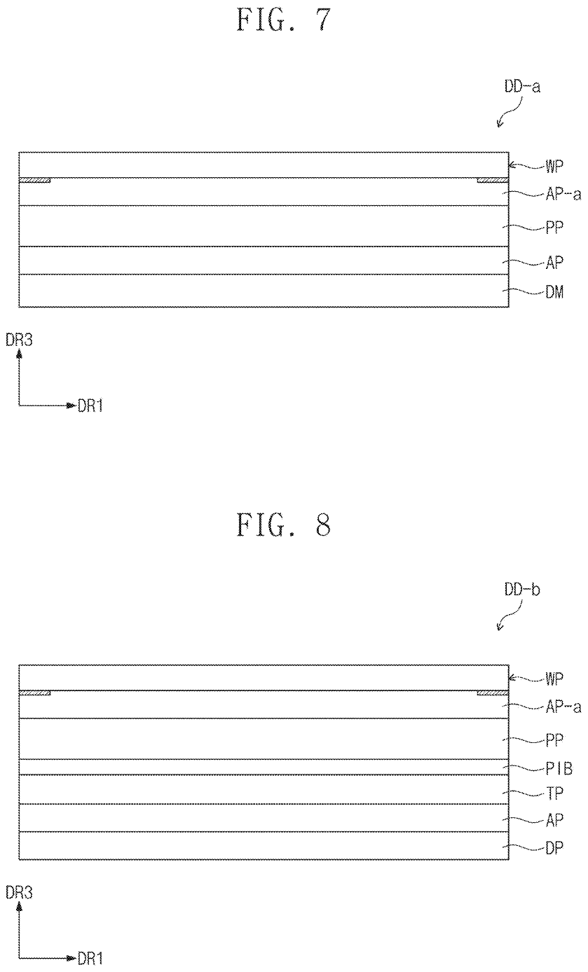

FIG. 7 is a cross-sectional view that shows a display device according to another embodiment of the present disclosure. Hereinafter, in the description of the display device shown in FIG. 7, content that overlaps the one described with reference to FIGS. 1-6C will not be described again, and differences will be mainly described.

Compared with the display device DD described with reference to FIGS. 2 and 3, a display device DD-a shown in FIG. 7 may further include a light control layer PP and an optical adhesive layer AP-a. The display device DD-a according to one or more embodiments may further include a light control layer PP between the adhesive member AP and the window WP, and an optical adhesive layer AP-a between the light control layer PP and the window WP. The light control layer PP may include a polarizing plate. The light control layer PP may include a color filter layer.

The optical adhesive layer AP-a may be formed from the resin composition RC according to one or more embodiments. The optical adhesive layer AP-a including a polymer derived from the resin composition RC may have a 180° peel strength of about 1500 gf/25 mm or greater for at least one of a glass substrate or a polymer substrate at room temperature. The optical adhesive layer AP-a including a polymer derived from the resin composition RC may have a yellow index (YI) of about 1 or less after a light resistance test according to DIN75220. Accordingly, the optical adhesive layer AP-a including a polymer derived from the resin composition RC may exhibit excellent or suitable adhesive strength and excellent or suitable light resistance. The display device DD including the optical adhesive layer AP-a may exhibit excellent or suitable reliability and excellent or suitable display quality.

FIG. 8 is a cross-sectional view that shows a display device according to another embodiment of the present disclosure. Hereinafter, in the description of the display device according to one or more embodiments shown in FIG. 8, content that overlaps the one described with reference to FIGS. 1-7 will not be described again, and differences will be mainly described.

Compared with the display device DD described with reference to FIGS. 2 and 3, a display device DD-b according to one or more embodiments shown in FIG. 8 may further include a light control layer PP, an optical adhesive layer AP-a, and an interlayer adhesive layer PIB. As the display device DD-a according to one or more embodiments shown in FIG. 7, the display device DD-b according to one or more embodiments shown in FIG. 8 may further include the light control layer PP between the adhesive member AP and the window WP, and the optical adhesive layer AP-a between the light control layer PP and the window WP.

In the display device DD-b according to one or more embodiments, the adhesive member AP may be provided between the display panel DP and the input sensing portion TP. For example, the input sensing portion TP may not be directly on the display panel DP, and the display panel DP and the input sensing portion TP may be bonded through the adhesive member AP. For example, the adhesive member AP may be between the encapsulation layer TFE (FIG. 3) of the display panel DP and the input sensing portion TP.

The interlayer adhesive layer PIB may be provided below the light control layer PP. The interlayer adhesive layer PIB may be between the input sensing portion TP and the light control layer PP and may be formed of an adhesive material that has excellent or suitable moisture permeation prevention properties. For example, the interlayer adhesive layer PIB may be formed including polyisobutylene. The interlayer adhesive layer PIB may be on the input sensing portion TP to prevent corrosion of sensing electrodes of the input sensing portion TP. The display device DD-b according to one or more embodiments includes the optical adhesive layer AP-a and the adhesive member AP formed from the resin composition RC according to one or more embodiments, and the display device DD-b including the optical adhesive layer AP-a and the adhesive member AP may exhibit excellent or suitable reliability and excellent or suitable display quality.

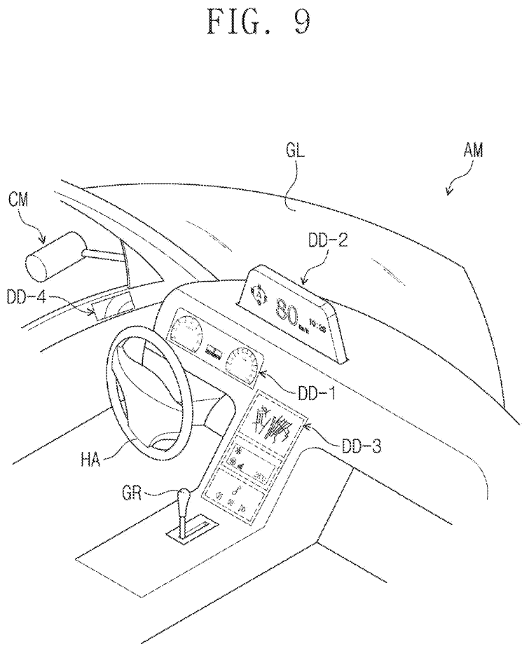

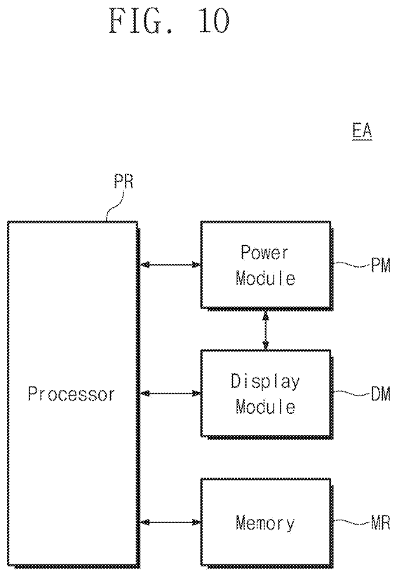

FIG. 9 is a view that shows a vehicle AM in which first to fourth display devices DD-1, DD-2, DD-3, and DD-4 are arranged. At least one of the first to fourth display devices DD-1, DD-2, DD-3, and DD-4 may have the same components as any one of the display devices DD, DD-a, and DD-b according to one or more embodiments described with reference to FIGS. 1-3, 7, and 8. At least one of the first to fourth display devices DD-1, DD-2, DD-3, and DD-4 may include the adhesive member AP according to one or more embodiments described with reference to FIGS. 1-3, 7, and 8.

FIG. 9 shows a car as the vehicle AM, but this is presented as an example, and the first to fourth display devices DD-1, DD-2, DD-3, and DD-4 may be on other means of transportation, such as bicycles, motorcycles, trains, ships, and airplanes. For example, at least one of the first to fourth display devices DD-1, DD-2, DD-3, and DD-4 including the same components as any one of the display devices DD, DD-a, and DD-b according to one or more embodiments may be adopted for other electronic apparatuses without departing from the present disclosure.

At least one of the first to fourth display devices DD-1, DD-2, DD-3, and DD-4 may include the adhesive member AP (FIG. 3) according to one or more embodiments. The adhesive member AP (FIG. 3) according to one or more embodiments is formed from the resin composition RC (FIGS. 5A and 6A) according to one or more embodiments, and may thus exhibit excellent or suitable adhesive strength and excellent or suitable light resistance.

The adhesive member AP according to one or more embodiments may have a 180° peel strength of about 2000 gf/25 mm or greater for at least one of a glass substrate or a polymer substrate at room temperature. The adhesive member AP according to one or more embodiments may have a yellow index (YI) of about 1 or less after a light resistance test according to DIN75220. Accordingly, a display device including the adhesive member AP (FIG. 3) according to one or more embodiments among the first to fourth display devices DD-1, DD-2, DD-3, and DD-4 may exhibit excellent or suitable reliability and excellent or suitable display quality.

Referring to FIG. 9, the vehicle AM may include a wheel HA and a gear GR for operating the vehicle AM, and have a front window GL arranged to face a driver.

The first display device DD-1 may be in a first region that overlaps the wheel HA. For example, the first display device DD-1 may be a digital cluster displaying first information of the vehicle AM. The first information may include a first scale indicating driving speed of the vehicle AM, a second scale indicating engine revolutions (i.e., revolutions per minute (RPM)), and an image indicating fuel gauge, and/or the like. The first scale and the second scale may be displayed as digital images.

The second display device DD-2 may be in a second region facing a driver seat and that overlaps the front window GL. The driver seat may be a seat in which the wheel HA is arranged. For example, the second display device DD-2 may be a head up display HUD displaying second information of the vehicle AM. The second display device DD-2 may be optically transparent. The second information includes digital numbers indicating driving speed of the vehicle AM and may further include information such as current time. Unlike what is shown, the second information of the second display device DD-2 may be projected and displayed on the front window GL.

The third display device DD-3 may be in a third region adjacent to the gear GR. For example, the third display device DD-3 may be a center information display CID for a vehicle, which is between a driver seat and a front passenger seat and displays third information. The passenger seat may be a seat spaced apart from the driver seat with the gear GR therebetween. The third information may include information about road conditions (e.g., navigation information), music or radio play, dynamic video (or image) play, temperature inside the vehicle AM, and/or the like.

The fourth display device DD-4 may be in a fourth region spaced apart from the wheel HA and the gear GR and adjacent to a side of the vehicle AM. For example, the fourth display device DD-4 may be a digital side mirror displaying fourth information. The fourth display device DD-4 may display images of conditions outside the vehicle AM, which are taken by a camera module CM outside the vehicle AM. The fourth information may include images of conditions outside the vehicle AM.

The first to fourth information described above are presented as an example, and the first to fourth display devices DD-1, DD-2, DD-3, and DD-4 may further display information about inside or outside a vehicle. The first to fourth information may include different information. However, an embodiment is not limited thereto, and some of the first to fourth information may include the same information.

FIG. 10 is a block diagram of an electronic apparatus according to one or more embodiments. Referring to FIG. 10, an electronic apparatus EA according to one or more embodiments may include a display module DM, a processor PR, a memory MR, and a power module PM.

The processor PR may include at least one of a central processing unit (CPU), an application processor (AP), a graphic processing unit (GPU), a communication processor (CP), an image signal processor (ISP), or a controller.

The memory MR may store data information required for the operation of the processor PR or the display module DM. When the processor PR executes an application stored in the memory MR, image data signals and/or input control signals are transmitted to the display module DM, and the display module DM may process the received signal and output image information through a display screen.

The power module PM may include a power supply module such as a power adapter or a battery device, and a power conversion module that converts power supplied by the power supply module to generate power required for the operation of the electronic apparatus EA.

At least one of the components of the electronic apparatus EA described above may be included in the display device according to the above-described embodiments. For example, some of the individual modules functionally included in one module may be included in the display device, and others may be separately provided from the display device. For example, the display device may include a display module DM, and the processor PR, the memory MR, and the power module PM may be provided in the form of other devices within the electronic apparatus EA, rather than the display device.

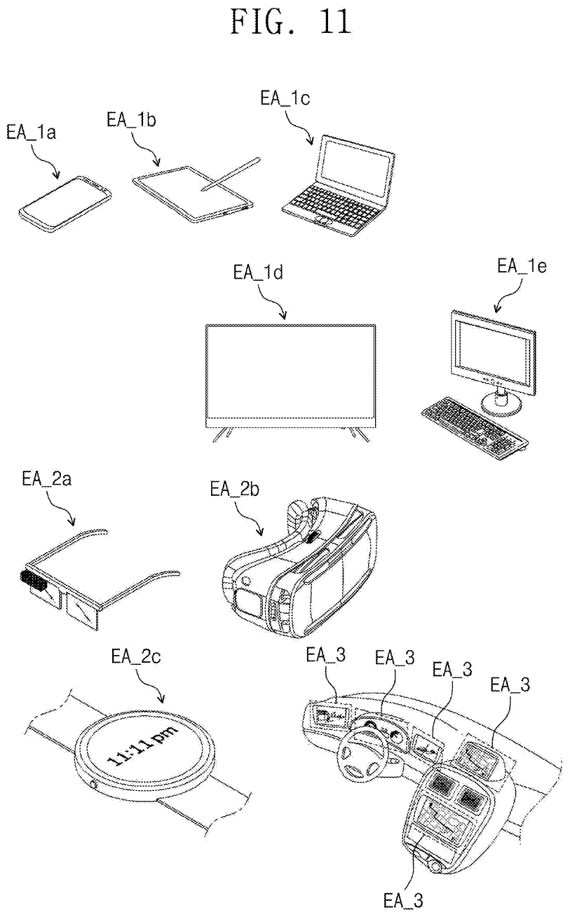

FIG. 11 shows schematic views of electronic apparatuses according to various suitable embodiments. Referring to FIG. 11, various suitable electronic apparatuses to which the display device according to embodiments is applied may include an electronic apparatus for displaying images, such as a smart phone EA_1a, a tablet PC EA_1b, a laptop EA_1c, a TV EA_1d, and a desk monitor EA_1e, a wearable electronic apparatus including a display module such as a smart glasses EA_2a, a head mounted display EA_2b, and a smart watch EA_2c, and a vehicle electronic apparatus EA_3 including a display module such as a center information display (CID) and a room mirror display on an instrument panel, a center fascia, or a dashboard of a vehicle.

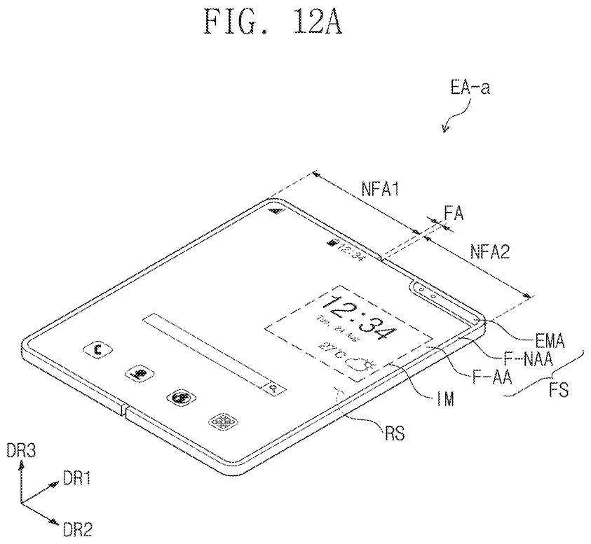

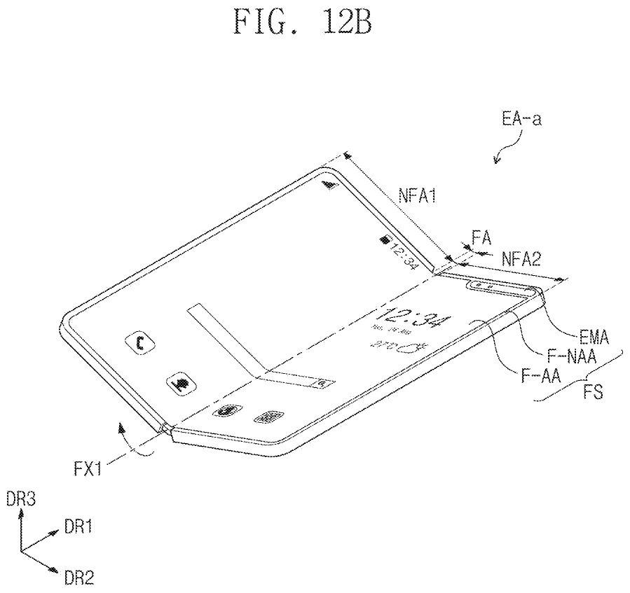

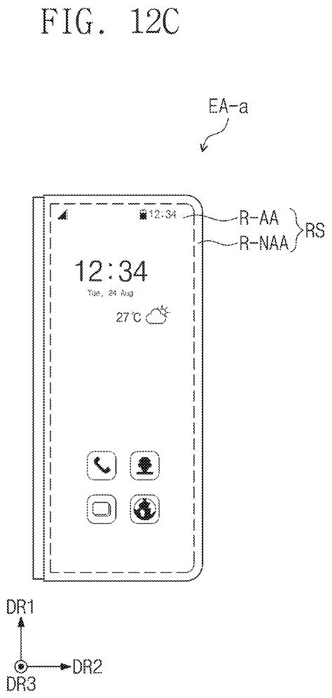

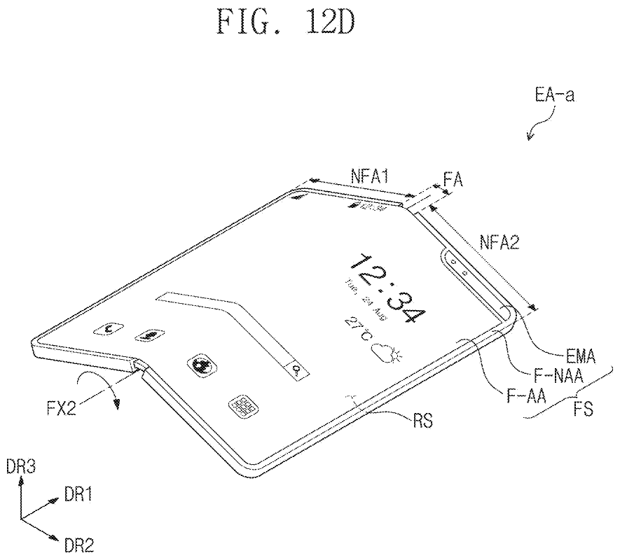

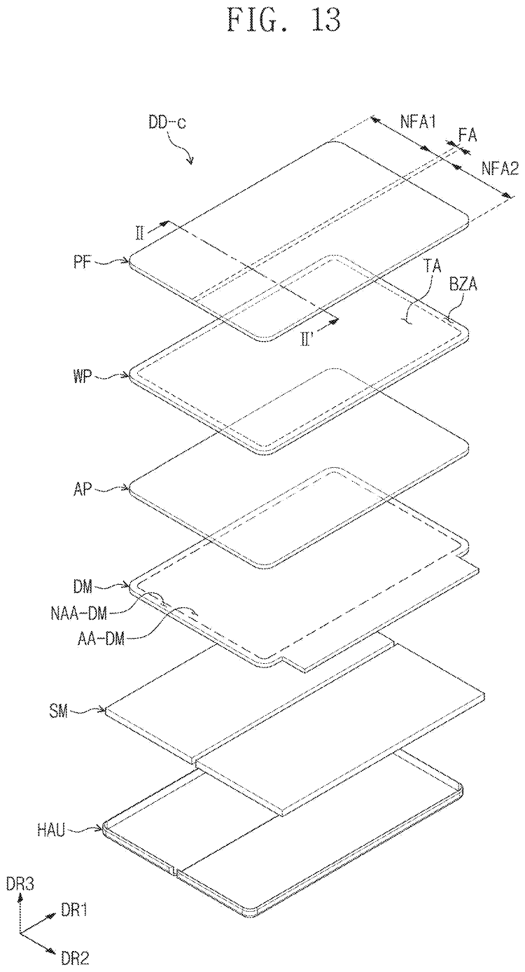

FIG. 12A is a perspective view that shows a state in which an electronic apparatus EA-a according to one or more embodiments is unfolded. Hereinafter, to provide descriptions with respect to the electronic apparatus EA-a according to one or more embodiments shown in FIG. 12A, descriptions that overlap the descriptions provided with reference to FIGS. 1-11 will not be provided again, and differences will be mainly described.

The electronic apparatus EA-a according to one or more embodiments may be a device activated in response to electrical signals. For example, the electronic apparatus EA-a may be a mobile phone, a tablet, a car navigation system, a game console, or a wearable device, but an embodiment is not limited thereto. In FIG. 12A and/or the like, a mobile phone is shown as an example of the electronic apparatus EA-a.

The electronic apparatus EA-a may include a first display surface FS defined by a first directional axis DR1 and a second directional axis DR2 crossing the first directional axis DR1. The electronic apparatus EA-a may provide an image IM to users through the first display surface FS. The electronic apparatus EA-a may display the image IM towards a third directional axis DR3 on the first display surface FS parallel to each of the first directional axis DR1 and the second directional axis DR2.

Herein, a front surface (or upper surface) and a rear surface (or lower surface) may oppose each other, and a normal direction of each of the front surface (or upper surface) and the rear surface (or lower surface) may be parallel to the third directional axis DR3. The front surface (or upper surface) indicates a surface adjacent to the first display surface FS, and the rear surface (or lower surface) indicates a surface spaced from the first display surface FS. For example, the rear surface (or lower surface) indicates a surface close to a second display surface RS. The upper surface indicates a direction towards the first display surface FS, and the lower surface indicates a direction away from the first display surface FS.

The electronic apparatus EA-a may sense external inputs applied from the outside. The external inputs may include various suitable forms of inputs provided from the outside the electronic apparatus EA-a. For example, the external inputs may include external inputs applied when approaching the electronic apparatus EA-a or being adjacent by a certain distance (e.g., hovering), as well as through contact by a part of a body such as a user's hand. For example, the external inputs may have various suitable forms such as force, pressure, temperature, light, and/or the like.

The electronic apparatus EA-a may include the first display surface FS and the second display surface RS. The first display surface FS may include a first active region F-AA, a first peripheral region F-NAA, and an electronic module region EMA. The second display surface RS may be defined as a surface opposing at least a portion of the first display surface FS. For example, the second display surface RS may be defined as a portion of the rear surface of the electronic apparatus EA-a.

The first active region F-AA may be a region activated according to electrical signals. The first active region F-AA may be a region displaying the image IM and sensing various suitable forms of external inputs.

The first peripheral region F-NAA may be adjacent to the first active region F-AA. The first peripheral region F-NAA may have color. The first peripheral region F-NAA may surround the first active region F-AA. Accordingly, the shape of the first active region F-AA may be substantially defined by the first peripheral region F-NAA. However, this is presented as an example, and the first peripheral region F-NAA may be adjacent to only one side of the first active region F-AA, or may not be provided.

The electronic module region EMA may have various suitable electronic modules arranged. For example, the electronic module may include at least any one of a camera, a speaker, a light detection sensor, or a heat detection sensor. The electronic module region EMA may sense an external subject received through the display surfaces FS and RS, or provide sound signals such as voice to the outside through the display surfaces FS and RS. The electronic modules may include a plurality of components, and are not limited to any one embodiment.

The electronic module region EMA may be surrounded by the first peripheral region F-NAA. However, this is merely an example, and the above-mentioned configuration is not limited to any one embodiment. For example, the electronic module region EMA may be surrounded by the first active region F-AA and the first peripheral region F-NAA, and the electronic module region EMA may be in the first active region F-AA.

The electronic apparatus EA-a according to one or more embodiments may be a flexible electronic apparatus. The electronic apparatus EA-a according to one or more embodiments may include at least one folding region FA and a plurality of non-folding regions NFA1 and NFA2 that extends from the folding region FA. For example, the first non-folding region NFA1, the folding region FA, and the second non-folding region NFA2 may be defined in the second direction DR2. The electronic apparatus EA-a according to one or more embodiments may include the first non-folding region NFA1 and the second non-folding region NFA2, which are spaced apart with the folding region FA1 therebetween in the second direction DR2. For example, the first non-folding region NFA1 may be arranged at one side of the folding region FA in the second direction DR2, and the second non-folding region NFA2 may be arranged at the other side of the folding region FA in the second direction DR2.

FIG. 12A and/or the like shows one or more embodiments of the electronic apparatus EA-a including one folding region FA, but an embodiment is not limited thereto, and in the electronic apparatus EA-a, a plurality of folding regions may be defined. For example, the electronic apparatus according to one or more embodiments may include two or more folding regions and three or more non-folding regions arranged with each of the folding regions therebetween.

FIG. 12B is a perspective view that shows a folding operation of the electronic apparatus EA-a according to one or more embodiments. FIG. 12C is a plan view that shows a state in which the electronic apparatus EA-a according to one or more embodiments is folded. FIG. 12D is a perspective view that shows a folding operation of the electronic apparatus EA-a according to one or more embodiments.

Referring to FIG. 12B, the electronic apparatus EA-a according to one or more embodiments may be folded with respect to a first folding axis FX1 that extends in the first direction DR1. When the electronic apparatus EA-a is folded, the folding region FA may have a slight curvature and radius of curvature. The electronic apparatus EA-a may be folded with respect to the first folding axis FX1 to become in-folded such that the first non-folding region NFA1 and the second non-folding region NFA2 face each other and the first display surface FS is not exposed to the outside.

Referring to FIG. 12C, in the state where the electronic apparatus EA-a according to one or more embodiments is in-folded, the second display surface RS may be viewed by users. For example, the second display surface RS may include a second active region R-AA displaying images. The second active region R-AA may be a region activated according to electrical signals. The second active region R-AA may be a region displaying images and sensing various suitable forms of external inputs.

A second peripheral region R-NAA may surround the second active region R-AA. The second peripheral region R-NAA may have color. The second peripheral region R-NAA may surround the second active region R-AA. For example, although not shown, the electronic apparatus EA-a may further include an electronic module region, in which an electronic module including various suitable components is arranged, in the second display surface RS, and is not limited to any one embodiment.

Referring to FIG. 12D, the electronic apparatus EA-a according to one or more embodiments may be folded with respect to a second folding axis FX2 that extends in the first direction DR1. When the electronic apparatus EA-a is folded, the folding region FA may have a slight curvature and radius of curvature. The electronic apparatus EA-a may be folded with respect to the second folding axis FX2 to become out-folded such that the first display surface FS is exposed to the outside. In one or more embodiments, the electronic apparatus EA-a may be configured such that the in-folding operation or the out-folding operation is mutually repeated from the unfolding operation, but is not limited thereto.

FIGS. 12A-12D show that the electronic apparatus EA-a is folded with respect to one folding axis FX1 or FX2 as examples, but the number of folding axes and the corresponding number of non-folding regions are not limited thereto. For example, the electronic apparatus EA-a may be folded with respect to a plurality of folding axes such that a portion of the first display surface FS faces a portion of the second display surface RS. For example, it is shown that the first and second folding axes FX1 and FX2 are directed parallel to a long side of the electronic apparatus EA-a, but an embodiment is not limited thereto, and the first and second folding axes FX1 and FX2 may be directed parallel to a short side of the electronic apparatus EA-a.

When the electronic apparatus EA-a is in the folded state as shown in FIG. 12C, the first non-folding region NFA1 and the second non-folding region NFA2 may be defined as portions that has display surfaces FS and RS directed parallel to a plane defined by the first directional axis DR1 and the second directional axis DR2, and the folding region FA may be defined as a region between the first non-folding region NFA1 and the second non-folding region NFA2. The folding region FA may include a curved surface portion which is bent to have a slight curvature in the folded state.

FIG. 13 is an exploded perspective view that shows a display device DD-c according to an embodiment. Hereinafter, to provide descriptions with respect to the display device DD-c according to one or more embodiments shown in FIG. 13, descriptions that overlap the descriptions provided with reference to FIGS. 1-12D will not be provided again, and differences will be mainly described.

The display device DD-c according to one or more embodiments may be included in the electronic apparatus EA-a (FIG. 12A) described above, thereby providing images. Referring to FIG. 13, the display device DD-c may include a display module DM, a window WP on the display module DM, and an adhesive member AP between the display module DM and the window WP. For example, the display device DD-c may further include a support member SM below the display module DM, a protection layer PF on the window WP, and a housing HAU accommodating the display module DM and the support member SM.

The support member SM may include a metal material or a polymer material. For example, the support member SM may be formed including stainless steel, aluminum, or an alloy thereof. In embodiments, the support member SM may be formed of carbon fiber reinforced plastic (CFRP) and/or the like. However, an embodiment is not limited thereto, and the support member SM may include a non-metal material, plastic, glass fiber reinforced plastic, or glass. Unlike what is shown, the support member SM may not be provided.

Although not shown, the display device DD-c may further include a cushion layer, a shielding layer, and/or the like below the support member SM. The cushion layer may include sponge, foam, or elastomer such as a urethane resin. The shielding layer may be an electromagnetic wave shielding layer or a heat dissipation layer.

The display module DM may be activated according to electrical signals. The display module DM may be activated to display the image IM (FIG. 12A) on the first display surface FS (FIG. 12A) of the display device DD-c. In the display module DM, an active region AA-DM and a peripheral region NNAA-DM may be defined. The active region AA-DM may be a region activated according to electrical signals. The peripheral region NNAA-DM may be a region adjacent to at least one side of the active region AA-DM. Circuits or lines for driving the active region AA-DM may be in the peripheral region NNAA-DM.

The adhesive member AP may be on the display module DM. The display module DM and the window WP may be bonded through the adhesive member AP. The adhesive member AP may be optically transparent. The adhesive member AP according to one or more embodiments may include a polymer derived from the resin composition RC (FIGS. 5A and 6A). The adhesive member AP may be formed from the resin composition RC (FIGS. 5A and 6A) according to one or more embodiments. The adhesive member AP according to one or more embodiments formed from the resin composition RC (FIGS. 5A and 6A) according to one or more embodiments may exhibit excellent or suitable adhesive strength and excellent or suitable light resistance. In one or more embodiments, the display device DD-c including the adhesive member AP formed from the resin composition RC (FIGS. 5A and 6A) may exhibit excellent or suitable reliability and excellent or suitable display quality.

The window WP may include a glass substrate. The window WP may protect the display module DM and/or the like. The image IM (FIG. 3A) generated from the display module DM may be provided to users by being transmitted through the window WP. For example, the window WP may include ultra thin glass (UTG).

The protection layer PF may be a functional layer that protects one surface (e.g., an upper surface) of the window WP. The protection layer PF may include an anti-fingerprint coating agent, a hard coating agent, an anti-static agent, and/or the like. Although not shown, an auxiliary adhesive layer may be between the window WP and the protection layer PF. Unlike what is shown, the protection layer PF may not be provided.

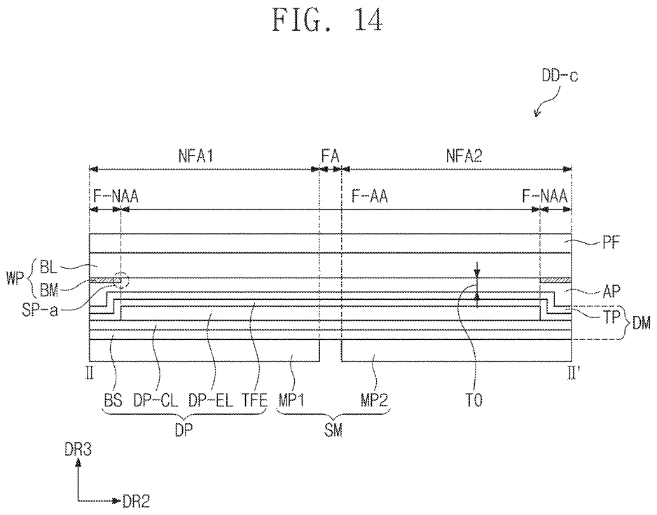

FIG. 14 is a cross-sectional view that shows a portion corresponding to line II-II′ of FIG. 13. FIG. 14 may be a cross-sectional view that shows the display device DD-c according to one or more embodiments. In FIG. 14, for convenience of description, the housing HAU is not provided, and the support member SM, the display module DM, the adhesive member AP, the window WP, and the protection layer PF are shown. Hereinafter, to provide descriptions with respect to the display device DD-c according to one or more embodiments shown in FIG. 14, descriptions that overlap the descriptions provided with reference to FIGS. 1-13 will not be provided again, and differences will be mainly described.

Referring to FIG. 14, the support member SM may include a first support portion MP1 that overlaps the first non-folding region NFA1 and a second support portion MP2 that overlaps the second non-folding region NFA2. The first support portion MP1 and the second support portion MP2 may be spaced apart in the folding region FA. The first support portion MP1 and the second support portion MP2 may non-overlap the folding region FA. Unlike what is shown, at least a portion of the first support portion MP1 and at least a portion of the second support portion MP2 may overlap the folding region FA.

A step SP-a may be present between the printing layer BM and a portion of the base layer BL on which the printing layer BM is not provided. The adhesive member AP formed from the resin composition RC (FIGS. 5A and 6A) according to one or more embodiments has excellent or suitable adhesive strength, and may thus be attached to the window WP without lifting at the step SP-a.

Hereinafter, with reference to Examples and Comparative Examples, the resin composition according to one or more embodiments of the present disclosure and the adhesive member formed from the resin composition will be specifically described herein. For example, Examples below are shown only for the understanding of the present disclosure, and the scope of the present disclosure is not limited thereto.

### EXAMPLES

### 1. Synthesis of (meth)acrylate oligomer

(Meth)acrylate oligomers of A-1 to A-5 provided in resin compositions of the Examples and Comparative Examples were synthesized through the following method. The (meth)acrylate oligomers of A-1 to A-3 are (meth)acrylate oligomers including dicyclopentenyl of the Examples, the (meth)acrylate oligomer of A-4 is a (meth)acrylate oligomer including dicyclopentanyl of the Comparative Example, and the (meth)acrylate oligomer of A-5 is a (meth)acrylate oligomer including t-butyl cyclohexyl of the Comparative Example.

Molecular weight of the (meth)acrylate oligomers was measured using a gel permeation chromatography (GPC) analyzer HLC-8420GPC from TOSOH Corporation. TSKgel SUPER HZM-N was used as a measurement column, and weight-average molecular weight values were applied by standard polystyrene (PS) conversion from a size exclusion chromatography (SEC) curve detected by a refractive index (RI) detector.

Composition ratio of the (meth)acrylate oligomers was calculated from an integral ratio of signals measured from each monomer component in the proton NMR spectrum, using a nuclear magnetic resonance (NMR) analyzer ‘AVANCE III 300M’ from Bruker. For example, deuterated chloroform (product from Kanto Chemical) was used as a deuterated solvent in the measurements.

Glass transition temperature of the (meth)acrylate oligomers was measured using differential scanning calorimetry (DSC) Photo-DSC 204 Phoenix from NETZSCH, at a heating rate of 10 K/min.

### Synthesis of (meth)acrylate oligomer A-1

To a round bottom flask equipped with a condenser, a dropping funnel, a nitrogen inlet tube, and a magnetic stirrer, 100 mL of propylene glycol 1-monomethyl ether was added, and the mixture was stirred at room temperature for 30 minutes while bubbling nitrogen to deoxygenate the solvent. Thereafter, the resulting product was heated in an oil bath up to 100 °C, and then a homogeneous solution of 37.5 g of methyl methacrylate (MMA, Tokyo Chemical Industry Co., Ltd.), 22.2 g of isobornyl methacrylate (IBXMA, Tokyo Chemical Industry Co., Ltd.), 5.1 g of dicyclopentenyl acrylate (FA-511AS, Resonac Corporation), 4.2 g of V-501 (4,4′-azobis(4-cyanovaleric acid), Fujifilm Wako Pure Chemical Industries, Ltd.), and 25 mL of 1,3-dimethyl-2-imidazolidinone was prepared in advance and added to a dropping funnel, and a cock was opened to slowly add the mixture dropwise into the flask over the course of an hour. Then, the resulting product was stirred over the course of an hour to perform a polymerization reaction and obtain a sample. Thereafter, 1000 mL of 58 vol % ethanol aqueous solution (Fujifilm Wako Pure Chemical Industries, Ltd.) was added to the beaker and stirred with the magnetic stirrer, and the sample was added dropwise in portions to extract the precipitate. The precipitate was filtered by suction filtration, washed, and filtered with a 58 vol % aqueous ethanol solution (Fujifilm Wako Pure Chemical Industries, Ltd.) to remove the polymerization solvent and unreacted monomer. Subsequently, the precipitate was dried under reduced pressure to obtain (meth)acrylate oligomer A-1. The (meth)acrylate oligomer A-1 had a weight-average molecular weight of 9,900 g/mol, and a polydispersity index of 1.43. The (meth)acrylate oligomer A-1 had a composition ratio of MMA:IBXMA:FA-511AS=75.4:19.6:5.0, and a glass transition temperature (Tg) was 113 °C.

### Synthesis of (meth)acrylate oligomer A-2

To a round bottom flask equipped with a condenser, a dropping funnel, a nitrogen inlet tube, and a magnetic stirrer, 100 mL of propylene glycol 1-monomethyl ether was added, and the mixture was stirred at room temperature for 30 minutes while bubbling nitrogen to deoxygenate the solvent. Thereafter, the resulting product was heated in an oil bath up to 100 °C, and then a homogeneous solution of 37.5 g of methyl methacrylate (MMA, Tokyo Chemical Industry Co., Ltd.), 22.2 g of isobornyl methacrylate (IBXMA, Tokyo Chemical Industry Co., Ltd.), 6.6 g of dicyclopentenyl oxyethyl methacrylate (FA-512M, Resonac Corporation), 4.2 g of V-501 (4,4′-azobis(4-cyanovaleric acid), Fujifilm Wako Pure Chemical Industries, Ltd.), and 25 mL of 1,3-dimethyl-2-imidazolidinone was prepared in advance and added to a dropping funnel, and a cock was opened to slowly add the mixture dropwise into the flask over the course of an hour. Then, the resulting product was stirred over the course of an hour to perform a polymerization reaction and obtain a sample. Thereafter, 1000 mL of 58 vol % ethanol aqueous solution (Fujifilm Wako Pure Chemical Industries, Ltd.) was added to the beaker and stirred with the magnetic stirrer, and the sample was added dropwise in portions to extract the precipitate. The precipitate was filtered by suction filtration, washed, and filtered with a 58 vol % aqueous ethanol solution (Fujifilm Wako Pure Chemical Industries, Ltd.) to remove the polymerization solvent and unreacted monomer. Subsequently, the precipitate was dried under reduced pressure to obtain (meth)acrylate oligomer A-2. The (meth)acrylate oligomer A-2 had a weight-average molecular weight of 10,200 g/mol, and a polydispersity index of 1.42. The (meth)acrylate oligomer A-2 had a composition ratio of MMA:IBXMA:FA-512M=75.3:19.7:5.0, and a glass transition temperature (Tg) was 101 °C.

### Synthesis of (meth)acrylate oligomer A-3

To a round bottom flask equipped with a condenser, a dropping funnel, a nitrogen inlet tube, and a magnetic stirrer, 100 mL of propylene glycol 1-monomethyl ether was added, and the mixture was stirred at room temperature for 30 minutes while bubbling nitrogen to deoxygenate the solvent. Thereafter, the resulting product was heated in an oil bath up to 100 °C, and then a homogeneous solution of 35.0 g of methyl methacrylate (MMA, Tokyo Chemical Industry Co., Ltd.), 22.2 g of isobornyl methacrylate (IBXMA, Tokyo Chemical Industry Co., Ltd.), 13.1 g of dicyclopentenyl oxyethyl methacrylate (FA-512M, Resonac Corporation), 4.2 g of V-501 (4,4′-azobis(4-cyanovaleric acid), Fujifilm Wako Pure Chemical Industries, Ltd.), and 25 mL of 1,3-dimethyl-2-imidazolidinone was prepared in advance and added to a dropping funnel, and a cock was opened to slowly add the mixture dropwise into the flask over the course of an hour. Then, the resulting product was stirred over the course of an hour to perform a polymerization reaction and obtain a sample. Thereafter, 1000 mL of 58 vol % ethanol aqueous solution (Fujifilm Wako Pure Chemical Industries, Ltd.) was added to the beaker and stirred with the magnetic stirrer, and the sample was added dropwise in portions to extract the precipitate. The precipitate was filtered by suction filtration, washed, and filtered with a 58 vol % aqueous ethanol solution (Fujifilm Wako Pure Chemical Industries, Ltd.) to remove the polymerization solvent and unreacted monomer. Subsequently, the precipitate was dried under reduced pressure to obtain (meth)acrylate oligomer A-3. The (meth)acrylate oligomer A-3 had a weight-average molecular weight of 10,300 g/mol, and a polydispersity index of 1.42. The (meth)acrylate oligomer A-3 had a composition ratio of MMA:IBXMA:FA-512M=72.9:17.4:9.7, and a glass transition temperature (Tg) was 89 °C.

### Synthesis of (meth)acrylate oligomer A-4

To a round bottom flask equipped with a condenser, a dropping funnel, a nitrogen inlet tube, and a magnetic stirrer, 100 mL of propylene glycol 1-monomethyl ether was added, and the mixture was stirred at room temperature for 30 minutes while bubbling nitrogen to deoxygenate the solvent. Thereafter, the resulting product was heated in an oil bath up to 100 °C, and then a homogeneous solution of 40.0 g of methyl methacrylate (MMA, Tokyo Chemical Industry Co., Ltd.), 20.6 g of dicyclopentanyl acrylate (FA-513AS, Resonac Corporation), 4.2 g of V-501 (4,4′-azobis(4-cyanovaleric acid), Fujifilm Wako Pure Chemical Industries, Ltd.), and 25 mL of 1,3-dimethyl-2-imidazolidinone was prepared in advance and added to a dropping funnel, and a cock was opened to slowly add the mixture dropwise into the flask over the course of an hour. Then, the resulting product was stirred over the course of an hour to perform a polymerization reaction and obtain a sample. Thereafter, 1000 mL of 58 vol % ethanol aqueous solution (Fujifilm Wako Pure Chemical Industries, Ltd.) was added to the beaker and stirred with the magnetic stirrer, and the sample was added dropwise in portions to extract the precipitate. The precipitate was filtered by suction filtration, washed, and filtered with a 58 vol % aqueous ethanol solution (Fujifilm Wako Pure Chemical Industries, Ltd.) to remove the polymerization solvent and unreacted monomer. Subsequently, the precipitate was dried under reduced pressure to obtain (meth)acrylate oligomer A-4. The (meth)acrylate oligomer A-4 had a weight-average molecular weight of 9,400 g/mol, and a polydispersity index of 1.46. The (meth)acrylate oligomer A-4 had a composition ratio of MMA:FA-513AS=79.2:20.8, and a glass transition temperature (Tg) was 111 °C.

### Synthesis of (meth)acrylate oligomer A-5

To a round bottom flask equipped with a condenser, a dropping funnel, a nitrogen inlet tube, and a magnetic stirrer, 100 mL of propylene glycol 1-monomethyl ether was added, and the mixture was stirred at room temperature for 30 minutes while bubbling nitrogen to deoxygenate the solvent. Thereafter, the resulting product was heated in an oil bath up to 100 °C, and then a homogeneous solution of 40.0 g of methyl methacrylate (MMA, Tokyo Chemical Industry Co., Ltd.), 21.0 g of 4-tert-butylcyclohexyl acrylate (TBCHA, Tokyo Chemical Industry Co., Ltd.), 4.2 g of V-501 (4,4′-azobis(4-cyanovaleric acid), Fujifilm Wako Pure Chemical Industries, Ltd.), and 25 mL of 1,3-dimethyl-2-imidazolidinone was prepared in advance and added to a dropping funnel, and a cock was opened to slowly add the mixture dropwise into the flask over the course of an hour. Then, the resulting product was stirred over the course of an hour to perform a polymerization reaction and obtain a sample. Thereafter, 1000 mL of 58 vol % ethanol aqueous solution (Fujifilm Wako Pure Chemical Industries, Ltd.) was added to the beaker and stirred with the magnetic stirrer, and the sample was added dropwise in portions to extract the precipitate. The precipitate was filtered by suction filtration, washed, and filtered with a 58 vol % aqueous ethanol solution (Fujifilm Wako Pure Chemical Industries, Ltd.) to remove the polymerization solvent and unreacted monomer. Subsequently, the precipitate was dried under reduced pressure to obtain (meth)acrylate oligomer A-5. The (meth)acrylate oligomer A-5 had a weight-average molecular weight of 9,400 g/mol, and a polydispersity index of 1.45. The (meth)acrylate oligomer A-5 had a composition ratio of MMA:TBCHA=82.1:17.9, and a glass transition temperature (Tg) was 99 °C.

The (meth)acrylate oligomers A-1 to A-3, that has a weight-average molecular weight of 5,000 g/mol to 20,000 g/mol, satisfy the weight-average molecular weight of the (meth)acrylate oligomer according to one or more embodiments. The (meth)acrylate oligomers A-1 to A-3, that has a polydispersity index of 1.0 to 3.0, satisfy the polydispersity index of the (meth)acrylate oligomer according to one or more embodiments. The (meth)acrylate oligomers A-1 to A-3, that has a glass transition temperature of 80 °C to 120 °C, satisfy the glass transition temperature of the (meth)acrylate oligomer according to one or more embodiments.

### 2. Preparation of Resin Composition

Resin compositions of the Examples and Comparative Examples were prepared using materials listed in Table 1. The materials described in Table 1 were weighed in a light-shielding poly container and stirred at room temperature to prepare resin compositions of the Examples and Comparative Examples.

### 3. Preparation and Evaluation of Adhesive Member

After the 180° peel strength and light resistance test in the adhesive members formed from the resin compositions of the Examples and Comparative Examples, yellow index (YI) was evaluated and shown in Table 1. The adhesive members of Examples were each formed from the resin compositions of the Examples 1 to 3. For example, the adhesive members of the Comparative Examples were each formed from the resin compositions of the Comparative Examples 1 to 3.

### Measurement of 180° Peel Strength of Adhesive Member

The resin compositions of the Examples and Comparative Examples were applied to a thickness of 150 μm onto a 26 mm×76 mm soda-lime glass (Central Glass Co., Ltd.) using a bar coater. The resin composition-applied soda-lime glass was irradiated with UV light using a UV-LED lamp that has peaks at wavelengths of 405 nm and 365 nm such that an integrated light intensity of each light was 450 mJ/cm² and 800 mJ/cm². A 20 mm×150 mm PET film (A4360 50 μm, manufactured by Toyobo Co., Ltd.) was bonded to the soda-lime glass irradiated with UV light at a bonding pressure of 0.15 MPa to obtain a sample.

The obtained sample was tested at a speed of 300 mm/min with a peel angle of 180°, using a universal testing machine (Instron Corporation, type 5965) to measure peel strength. An average value for about 50 mm of peel was obtained, and the obtained value was multiplied by 1.25 to record the peel strength for a width of 25 mm in Table 1.

### Measurement of Yellow Index of Adhesive Member

The resin compositions of the Examples and Comparative Examples were provided between slide glasses (Slide Glass S1112, manufactured by Matsunami Glass) with a 200 μm-thick spacer attached. The resin compositions were cured through irradiation with UV light using a UV-LED lamp that has peaks at wavelengths of 405 nm and 365 nm such that an integrated light intensity of each light was 450 mJ/cm² and 800 mJ/cm².

The obtained samples were tested for light resistance, and yellow index was measured before and after the light resistance test using a COH7700 spectrophotometer (manufactured by Nippon Denshoku Kogyo Co., Ltd.). The light resistance test was performed in accordance with DIN 75220, through irradiation of UV light with a wavelength of 280 nm to 3000 nm at a total intensity of 1120 W/m² for 80 hours.

TABLE 1

| | | | | | | Comparative | | |
|---|---|---|---|---|---|---|---|---|
| | | | Example | | | Example | | |
| | | | 1 | 2 | 3 | 1 | 2 | 3 |
| Composition | (Meth)acrylate | A-1 | 10 | | | | | |
| | oligomer | A-2 | | 10 | | | | |
| | | A-3 | | | 10 | | | |
| | | A-4 | | | | | 10 | |
| | | A-5 | | | | | | 10 |
| | Photoradical | Omnirad | 1 | 1 | 1 | 1 | 1 | 1 |
| | polymerization | 819 | | | | | | |
| | initiator | | | | | | | |
| | (Meth)acrylate | 4-HBA | 10 | 10 | 10 | 10 | 10 | 10 |
| | monomer | IDAA | 50 | 50 | 50 | 50 | 50 | 50 |
| | | THF-A | 15 | 15 | 15 | 15 | 15 | 15 |
| | | IBXA | 10 | 10 | 10 | 10 | 10 | 10 |
| | | FA-512AS | 0 | 0 | 0 | 10 | 0 | 0 |
| | Urethane | UV-3300B | 4 | 4 | 4 | 4 | 4 | 4 |
| | (meth)acrylate | | | | | | | |
| | oligomer | | | | | | | |

Evaluation of adhesive member

| | | | | | | |
|---|---|---|---|---|---|---|
| 180° peel strength (gf/25 mm) at room temperature | 2400 | 2200 | 2100 | 50 | 1500 | 1600 |
| Yellow Index (YI) | 0.8 | 0.8 | 0.7 | 1.1 | 1.4 | 1.5 |

### Data on Materials in Table 1

Omnirad 819: Phenylbis(2,4,6-trimethyl benzoyl)phosphine oxide (manufactured by IGM Resins)
4-HBA: 4-hydroxybutyl acrylate (manufactured by Osaka Organic Chemical Industry Co., Ltd.)
IDAA: Isodecyl acrylate (manufactured by Osaka Organic Chemical Industry Co., Ltd.)
THF-A: Tetrahydrofurfuryl acrylate (manufactured by Kyoeisha Chemical Co., Ltd.)
IBXA: Isobornyl acrylate (manufactured by Osaka Organic Chemical Industry Co., Ltd.)
FA-512AS: Dicyclopentenyloxyethyl acrylate (manufactured by Resonac Corporation)
UV-3300B: Urethane acrylate (weight-average molecular weight: 13,000, manufactured by Mitsubishi Chemical Corporation)

Referring to Table 1, it is seen that in the resin compositions of the Examples and Comparative Examples, the photoradical polymerization initiator is provided as the same material and in the same weight. It is seen that in the resin compositions of the Examples and Comparative Examples, the (meth)acrylate monomer includes 4-hydroxybutyl acrylate (4-HBA), isodecyl acrylate (IDAA), tetrahydrofurfuryl acrylate (THF-A), and isobornyl acrylate (IBXA). It is seen that in the resin compositions of the Examples and Comparative Examples, the urethane (meth)acrylate oligomer is provided as the same material and in the same weight. It is seen that the resin compositions of the Examples and Comparative Examples do not include a volatile organic solvent.

Each of the resin compositions of Examples 1 to 3 includes (meth)acrylate oligomers A-1 to A-3. As described above, the (meth)acrylate oligomers A-1 to A-3 correspond to (meth)acrylate oligomers containing dicyclopentenyl according to one or more embodiments.

The resin compositions of Comparative Examples 1 to 3 do not include (meth)acrylate oligomers containing dicyclopentenyl according to one or more embodiments. The resin composition of Comparative Example 1 includes a (meth)acrylate monomer containing dicyclopentenyl. The resin composition of Comparative Example 2 includes a (meth)acrylate oligomer containing dicyclopentanyl. The resin composition of Comparative Example 3 includes a (meth)acrylate oligomer containing t-butyl cyclohexyl.

Referring to Table 1, it is seen that the adhesive members formed from the resin compositions of Examples 1 to 3 have a 180° peel strength of about 2000 gf/25 mm or greater for at least one of a glass substrate or a polymer substrate at room temperature. It is seen that the adhesive members formed from the resin compositions of Examples 1 to 3 have a yellow index of 1 to 3 after the light resistance test in accordance with DIN75220. For example, it is seen that the adhesive members formed from the resin compositions of Examples 1 to 3 satisfy the 180° peel strength and yellow index according to one or more embodiments. Therefore, it is seen that an adhesive member formed from a resin composition including a (meth)acrylate oligomer including a (meth)acrylate monomer that has a dicyclopentenyl skeleton in a side chain exhibits high adhesive strength and excellent or suitable light resistance, and an electronic apparatus including the adhesive member exhibits excellent or suitable display quality and excellent or suitable reliability.

The adhesive members formed from the resin compositions of Comparative Examples 1 to 3 have a 180° peel strength of less than 2000 gf/25 mm for at least one of a glass substrate or a polymer substrate at room temperature. The adhesive members formed from the resin compositions of Comparative Examples 1 to 3 have a yellow index of greater than 1 after the light resistance test in accordance with DIN75220. As described above, the resin compositions of Comparative Examples 1 to 3, unlike the resin compositions of Examples 1 to 3, do not include a (meth)acrylate oligomer including a (meth)acrylate monomer that has a dicyclopentenyl skeleton in a side chain. Accordingly, it is seen that the adhesive members formed from the resin compositions of Examples 1 to 3 exhibit low 180° peel strength and low light resistance.

An electronic apparatus according to one or more embodiments may include an adhesive member between a display module and a window, and the adhesive member may include a polymer derived from the resin composition according to one or more embodiments. The adhesive member may be formed by curing the resin composition according to one or more embodiments. The resin composition according to one or more embodiments may be provided on one surface of the display module or one surface of the window and may be cured by light passing through the printing layer for irradiation to form the adhesive member.

The resin composition according to one or more embodiments may include at least one (meth)acrylate oligomer including a (meth)acrylate monomer that has a dicyclopentenyl skeleton in a side chain, at least one (meth)acrylate monomer including a (meth)acryloyl group, at least one urethane (meth)acrylate oligomer, and at least one photoradical polymerization initiator, and may not include a volatile organic solvent. The adhesive member according to one or more embodiments may be formed from the resin composition according to one or more embodiments. The adhesive member according to one or more embodiments may have a 180° peel strength of about 2000 gf/25 mm or greater for at least one of a glass substrate or a polymer substrate at room temperature. For example, the adhesive member may have a yellow index of about 1 or less after a light resistance test according to DIN75220. Accordingly, the adhesive member according to one or more embodiments may exhibit high adhesive strength and excellent or suitable light resistance. For example, an electronic apparatus including the adhesive member according to one or more embodiments may exhibit excellent or suitable display quality and excellent or suitable reliability.

A resin composition according to one or more embodiments includes a (meth)acrylate monomer that has a dicyclopentenyl skeleton in a side chain, and may thus exhibit high adhesive properties and excellent or suitable light resistance after curing.

An adhesive member according to one or more embodiments and an electronic apparatus including the adhesive member include a polymer derived from a resin composition according to one or more embodiments, and may thus exhibit excellent or suitable reliability and excellent or suitable display quality.

In the above, description has been made with reference to embodiments of the present disclosure, but those skilled or of ordinary skill in the art may understand that various suitable modifications and changes may be made to the present disclosure insofar as such modifications and changes do not depart from the spirit and technical scope of the present disclosure set forth in the appended claims.

Therefore, the technical scope of the present disclosure is not to be limited to the contents stated in the detailed description of the disclosure, but should be determined by the appended claims.

What is claimed is:

1. A resin composition comprising:
at least one (meth)acrylate oligomer comprising a (meth)acrylate monomer that has a dicyclopentenyl skeleton in a side chain;
at least one (meth)acrylate monomer comprising a (meth)acryloyl group;
at least one urethane (meth)acrylate oligomer; and
at least one photoradical polymerization initiator,
wherein the resin composition does not comprise a volatile organic solvent.

2. The resin composition of claim 1, wherein the (meth)acrylate oligomer has a glass transition temperature of 80 °C or greater.

3. The resin composition of claim 1, wherein the (meth)acrylate oligomer has a weight-average molecular weight of 5,000 g/mol to 20,000 g/mol.

4. The resin composition of claim 1, wherein the (meth)acrylate oligomer has a polydispersity index of 1.0 to 3.0.

5. The resin composition of claim 1, wherein the (meth)acrylate monomer that has the dicyclopentenyl skeleton in a side chain is dicyclopentenyl (meth)acrylate or dicyclopentenyl oxyethyl(meth)acrylate.

6. The resin composition of claim 1, that has a 180° peel strength of 2000 gf/25 mm or greater for at least one of a glass substrate or a polymer substrate at room temperature after photocuring.

7. The resin composition of claim 1, wherein the resin composition is provided through inkjet printing or dispensing.

8. An adhesive member comprising a polymer derived from a resin composition,
wherein the resin composition comprises:
at least one (meth)acrylate oligomer comprising a (meth)acrylate monomer that has a dicyclopentenyl skeleton in a side chain;
at least one (meth)acrylate monomer comprising a (meth)acryloyl group;
at least one urethane (meth)acrylate oligomer; and
at least one photoradical polymerization initiator, and
wherein the resin composition does not comprise a volatile organic solvent.

9. The adhesive member of claim 8, that has a 180° peel strength of 2000 gf/25 mm or greater for at least one of a glass substrate or a polymer substrate at room temperature.

10. The adhesive member of claim 8, that has a yellow index of 1 or less after a light resistance test according to DIN75220.

11. The adhesive member of claim 8, wherein the (meth)acrylate oligomer has a glass transition temperature of 80 °C or greater.

12. The adhesive member of claim 8, wherein the (meth)acrylate oligomer has a weight-average molecular weight of 5,000 g/mol to 20,000 g/mol.

13. The adhesive member of claim 8, wherein the (meth)acrylate oligomer has a polydispersity index of 1.0 to 3.0.

14. The adhesive member of claim 8, wherein the (meth)acrylate monomer that has the dicyclopentenyl skeleton in a side chain is dicyclopentenyl (meth)acrylate or dicyclopentenyl oxyethyl(meth)acrylate.

15. The adhesive member of claim 8, wherein the resin composition is provided through inkjet printing or dispensing.

16. An electronic apparatus comprising:
a display module;
a window on the display module; and
an adhesive member between the display module and the window and comprising a polymer derived from a resin composition, wherein the resin composition comprises at least one (meth)acrylate oligomer comprising a (meth)acrylate monomer that has a dicyclopentenyl skeleton in a side chain, at least one (meth)acrylate monomer comprising a (meth)acryloyl group, at least one urethane (meth)acrylate oligomer, and at least one photoradical polymerization initiator, and does not comprise a volatile organic solvent.

17. The electronic apparatus of claim 16, wherein the adhesive member has a 180° peel strength of 2000 gf/25 mm or greater for at least one of a glass substrate or a polymer substrate at room temperature.

18. The electronic apparatus of claim 16, wherein the adhesive member has a yellow index of 1 or less after a light resistance test according to DIN75220.

19. The electronic apparatus of claim 16, wherein the window comprises a base layer and a printing layer between the adhesive member and the base layer, and
the resin composition provided on one surface of the display module or one surface of the window is cured by light passing through the printing layer for irradiation to form the adhesive member.

20. The electronic apparatus of claim 16, further comprising at least one of a processor, a memory, or a power module.
